(19) United States
(12) Patent Application Publication
(10) Pub. No.: US 2025/0072159 A1
(43) Pub. Date: Feb. 27, 2025

(54) GIANT FERROELECTRIC AND OPTOELECTRONIC RESPONSES OF FIELD EFFECT TRANSISTORS BASED ON MONOLAYER SEMICONDUCTING TRANSITION METAL DICHALCOGENIDES

(71) Applicant: California Institute of Technology, Pasadena, CA (US)

(72) Inventors: Nai-Chang Yeh, Pasadena, CA (US); Duxing Hao, Pasadena, CA (US); Yann-Wen Lan, Taipei (TW); Ting-Hua Lu, Taipei (TW)

(73) Assignees: California Institute of Technology, Pasadena, CA (US); National Taiwan Normal University, Taipei City (TW)

(21) Appl. No.: 18/748,641

(22) Filed: Jun. 20, 2024

Related U.S. Application Data
(60) Provisional application No. 63/522,071, filed on Jun. 20, 2023.

(51) Int. Cl. H01L 31/0352; G01R 33/12; H01L 31/032

(52) U.S. Cl. CPC H01L 31/035236; G01R 33/1284; H01L 31/032; H01L 31/035227

(57) ABSTRACT

A field effect transistor including a substrate; a monolayer of a single crystal semiconducting transition metal dichalcogenide (TMD) on the substrate; a source contact and a drain contact to the strained monolayer; and a gate contact on the substrate; wherein the a gate voltage applied to the gate contact with respect to the source contact modulates a ferroelectric response of the monolayer when strained and a current through the monolayer between the source contact and the drain contact; and wherein the substrate is rigid and the monolayer experiences asymmetric lattice expansion when strained against the rigid substrate in response to an external magnetic field or the substrate is a strain engineered substrate inducing asymmetric lattice expansion of the monolayer.

### CROSS-REFERENCE TO RELATED APPLICATIONS

This application claims the benefit under 35 U.S.C. Section 119 (e) of co-pending and commonly-assigned U.S. Provisional Patent Application No. 63/522,071, filed Jun. 20, 2023, entitled “GIANT FERROELECTRIC AND OPTOELECTRONIC RESPONSES OF FIELD EFFECT TRANSISTORS BASED ON MONOLAYER SEMICONDUCTING TRANSITION METAL DICHALCOGENIDES” by Nai-Chang Yeh, Duxing Hao, Yann-Wen Lan, and Ting-Hua Lu, (CIT-9027) which application is incorporated by reference herein.

### FEDERALLY SPONSORED RESEARCH AND DEVELOPMENT

This invention was made with government support under Grant No. PHY1733907 awarded by the National Science Foundation. The government has certain rights in the invention.

### BACKGROUND OF THE INVENTION

Ferroelectric materials, which feature a polar point group in their unit cells, are crucial components for modern electronic applications, particularly in high-density data storage, microwave devices, pyroelectric sensors, non-volatile memories. However, in the ultrathin limit, depolarization effect severely suppresses the out-of-plane electric dipoles in most ferroelectric materials, resulting in diminishing ferroelectricity. Two-dimensional (2D) ferroelectric semiconductors, with their robust atomic-scale ferroelectricity and moderate bandgap, offer a potential solution by enabling in-memory computation and energy-efficient photovoltaics within a compact size. Recently, ferroelectricity has been observed in a two-layer van der Waals (vdW) interfaces using marginally twisted 2D materials that lack polar point groups in their parent lattices, such as boron nitride (BN) and transition metal dichalcogenides (TMDs). On the other hand, for 2H-TMDs in the monolayer limit, the D₃ₕ point group preserves the centrosymmetry so that there is no out-of-plane polarization nor ferroelectricity. If mirror symmetry breaking is introduced, however, the point group could reduce to a ferroelectric subgroup (P3m1). In the case of monolayer molybdenum disulfide (MoS₂) with a distorted-1T structure, a slight vertical displacement of intralayer sulfur atoms results in broken centrosymmetry and a net electric polarization along the out-of-plane direction, thus the emergence of ferroelectricity. However, due to domains of randomly orientated spontaneous polarization in the distorted-1T phase, a tip-induced flexoelectric training field would be needed to achieve polarization alignment before ferroelectricity could be detected by scanning probe microscopy. Prior to the present invention, no device-scale robust ferroelectricity has been reported in monolayer TMDs.

### SUMMARY OF THE INVENTION

Here we present a new discovery of giant magnetic field-induced ferroelectric responses in monolayer MoS₂ based on fully reproducible measurements on the field effect transistors (FETs) made of monolayer MoS₂. We demonstrate that the ferroelectric responses of monolayer MoS₂-FETs can be controlled by temperature (T), magnetic field (B), and the maximum back-gate voltage (V_{GS}) applied to the FETs, and provide experimental evidence to demonstrate that the physical origin for the giant field-induced ferroelectric responses is associated with the following three factors: 1) the breaking of crystalline centrosymmetry and 2) the excess electric/magnetic dipole moments due to sulfur vacancies, and 3) asymmetric lattice expansion between the top and bottom sulfur layers on a substrate at low temperatures (<20 K),

Based on these observations, we carried out molecular dynamics (MD) simulations to demonstrate that nanoscale strain-engineering of monolayer MoS₂ can induce significant broken centrosymmetry even in the absence of sulfur vacancies, which in principle can lead to strong ferroelectric responses without the need of applying an external magnetic field. We further discover sensitive responses of the ferroelectric signals from the monolayer MoS₂-FETs to light excitations as a function of the light frequency, polarization, and orbital angular momentum, which may be attributed to strong interactions between excitonic polaritons and photo-excited carriers with intrinsic electronic carriers in monolayer MoS₂. Our findings suggest that FETs based on monolayer MoS₂ and other semiconducting monolayer TMDs (e.g., MoSe₂, WS₂, WSe₂, and their alloys) may be used for miniature magnetic sensors, non-volatile memories, as well as optical sensors for detecting the frequency, polarization and angular momentum of twisted light. Our specific inventions are summarized below:

As illustrated herein, giant magnetic field (B)-induced ferroelectric responses in FETs based on monolayer MoS₂ single crystals appear at temperatures (T) below ˜20 K, as exemplified in FIG. 1b for different |I_{DS}|-vs.-V_{GS} hysteresis curves measured at temperature (T)=1.8 K under an out-of-plane magnetic field of B=9 T with V_{DS} fixed at −1 V, −0.8 V and −0.6 V, respectively, and in FIG. 1c for |I_{DS}|-vs.-V_{GS} hysteresis under different magnetic fields from −9 T to 9 T with V_{DS}=−1 V. Here I_{DS}, V_{GS} and V_{DS} denote the source-drain current, back-gate voltage and source-drain bias voltage, respectively. The counter-clockwise |I_{DS}|-vs.-V_{GS} hysteresis can be enhanced by increasing the maximum V_{GS} value, increasing |B|, and lowering T.

For T<20 K, the hysteresis window (V_{HW}) and the corresponding polarization P₀ of the monolayer MoS₂-FETs are found to increase with increasing out-of-plane magnetic field |B|, as exemplified in FIG. 1d, although they are independent of the values of V_{DS}. Here the hysteresis window V_{HW} is defined as V_{HW}≡V_{th,H}−V_{th,L} as detailed in Methods and FIG. 6.

Under a constant out-of-plane magnetic field |B| and a constant T<20 K, the maximum |I_{DS}| value of the |I_{DS}|-vs.-V_{GS} hysteresis loop is found to increase with the increasing maximum value of I_{GS}, as exemplified in FIG. 2a. Additionally, the hysteresis window (V_{HW}) under a constant |B| decreases with increasing temperature and vanishes at the Curie temperature T_{C} (FIG. 2c), and the Curie temperature T_{C} increases with |B| and saturates below 20 K (FIG. 2d).

There is a strong correlation between the magnitude of ferroelectricity and the density of sulfur vacancies in monolayer MoS₂, as discussed herein based on measurements of the electric hysteresis (from V_{HW}), Fermi level E_{F} (from Kelvin probe force microscopy), and concentration ratio of Mo/S (from STM imaging), as shown in FIGS. 18 and 19.

We demonstrated evidence for magnetic field-induced crystalline lattice expansion in monolayer MoS₂ from temperature and magnetic field dependent Raman spectroscopy and scanning tunneling microscopy at low temperatures, as shown in FIGS. 3 and 4. Based on these findings, we propose a phenomenological model that attributes the occurrence of ferroelectricity in monolayer MoS₂ to magnetic field-induced asymmetric lattice expansion between the top and bottom sulfur layers on a substrate at low temperatures

We performed MD simulations to examine how nanoscale strain engineering may break the centrosymmetry of monolayer TMDs. As exemplified in Appendix FIG. 1 for the strain tensors εₓₓ, ε_{yy} and ε_{xy} in each of the three atomic layers of a monolayer MoS₂ induced by a gold nano-tetrahedron of a base length d=1.46 nm and a rounded top as shown in FIG. 21a, with one of its edges aligned along the zigzag (x-axis) direction of MoS₂. Apparently the strain tensor components for the three atomic layers a monolayer MoS₂ are all different, yielding significant symmetry breaking particularly along the out-of-plane direction, which is expected to induce ferroelectricity, particularly in the presence of sulfur vacancies.

We discovered that illuminating twisted light with non-trivial photonic spin and orbital angular momenta (SAM/OAM) on the monolayer MoS₂ FETs not only induces excess photocurrents but also results in novel modifications to the ferroelectric responses, including reduction in the hysteresis loop size, which may be attributed to excess photo-excited carriers that effectively screen the electric polarization, as well as asymmetric effects associated with SAM and OAM photons of opposite signs, as exemplified in FIGS. 22a-d. The asymmetry may be attributed to in-plane symmetry breaking by the applied source-drain current, which results in excitations of Rydberg excitons with finite orbital angular momenta whose signs are determined by the source-drain current direction. We further note that the chiral asymmetry associated with the OAM light steadily increases with the increasing magnitude of the topological charge |l|, as shown in FIG. 22c. Moreover, interesting dependence on the wavelength and intensity of light is observed, as exemplified in FIGS. 22a-b for the wavelength dependence. Specifically, for SAM light and linearly polarized (LP) light, it appears that the magnitude of photocurrents increases with increasing photon energy. On the other hand, for on-resonance photon energy (i.e., photon energy equals to the semiconducting energy gap), photocurrents increase with the |l| value of the OAM light. These findings of novel optoelectronic phenomena associated with the interplay of topological photonics and symmetry breaking effects in atomically thin 2D quantum materials are unprecedented, which are promising for applications in ultra-compact photodetectors for decoding optical signals with nontrivial topological charges (i.e., nontrivial SAM/OAM).

### BRIEF DESCRIPTION OF DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIGS. 1a-1e|Magnetic-field induced giant hysteresis responses in ML-MoS₂ field-effect transistor (FET) at T=1.8 K. a, I_{DS}-vs.-V_{DS} transfer curve measured at a gate voltage (V_{GS}) from 13 V to 20 V with an increment of 1 V, showing largely ohmic characteristics. b, Main panel: |I_{DS}|-vs.-V_{GS} hysteresis curves measured under a magnetic field of 9 T with V_{DS} fixed at −1 V, −0.8 V and −0.6 V, respectively. Inset: |I_{DS}|-vs.-V_{GS} curve taken at B=0, showing absence of hysteresis. Black arrows in the main panel indicate the V_{GS} sweeping direction for the corresponding HRS/LRS states under different V_{DS} values, which reveal the counterclockwise hysteresis loops for all V_{DS} values at B=9 T. c, |I_{DS}|-vs.-V_{GS} hysteresis under magnetic field from 9 T to −9 T with V_{DS}=−1 V, showing characteristics independent of the sign of magnetic field within experimental errors, as further demonstrated in the semi-log inset for comparison of the hysteresis loops taken at B=9 T (red) and −9 T (blue). d, Hysteresis window V_{HW} as a function of out-of-plane magnetic field. e. Schematic of a system comprising the field effect transistor.

FIGS. 2a-2d| Gate voltage modulation of hysteresis and magnetic field-controlled critical temperature. a, Linear-scale (main panel) and semi-log-scale plot (inset) of |I_{DS}|-vs.-V_{GS} characteristics, showing different hysteresis loop sizes under different V_{GS} ranges. All measurements started at V_{GS}=2 V and ended at different V_{GS, max} values under the conditions of T=10 K, B=9 T and V_{DS}=−0.6 V. b, Characteristics voltages (V_{th, H}, V_{th, L}, V_{HW}) of the hysteresis loops in a are shown as a function of V_{GS, max.} C, Temperature dependence of |I_{DS}|-vs.-V_{GS} characteristics, showing a loop closing at T_{C}=19.3 K under a constant magnetic field of 12 T. The inset shows the emergence of V_{HW} and P₀ below T_{C}. d, Main panel: Determination of the critical temperature (T_{C}) from the V_{HW}-T plots under different constant magnetic fields, where T_{C}(B) is identified at the temperature where V_{HW}(B,T)=0. The inset shows a higher magnetic field leads to a higher T_{C}. Measurements were taken with V_{DS}=−1 V.

FIGS. 3a-3c|Raman characterizations of a ML-MoS₂ device under an out-of-plane magnetic field at 4.2 K: a,b, Raman spectra taken under B=0 (bottom) and an out-of-plane magnetic field B=0.5 T (top) at 300 K (a) and 4.2 K (b), respectively. c, The Raman peak positions for A_{1g} (blue square) and E_{2g} (orange triangle) at 300 K and 4.2 K with and without magnetic field. The red (green) dashed lines indicate the peak positions of A_{1g} and E_{2g} at 300 K (4.2 K) under B=0.

FIGS. 4a-4e| Magnetic field-induced ML-MoS₂ lattice expansion as characterized by scanning tuning microscopy (STM) and a proposed model for the effect of temperature and magnetic field on the structure of ML-MoS₂: a,b, Reconstructed moiré superlattice topography (top panels) and the corresponding filtered fast Fourier transformation (FFT; bottom panels) of ML-MoS₂/HOPG at 4.5 K for two (5 nm×5 nm) regions of the same sample: (a) one (5 nm×5 nm) region with a twist angle of 0.5° between MoS₂ and HOPG under B=0 and 0.5 T (green); and (b) the other (5 nm×5 nm) region with a twist angle of 3.1° between MoS₂ and HOPG under B=0.5 T, 3.0 T and 5.0 T (orange). The red and blue rhombus in the topographic images outline the unit cell of the moiré superlattice and the MoS₂ lattice, respectively. Red and blue circles in the FFT images outline the corresponding reciprocal lattice sites. The STM bias voltage was fixed at 0.1 V and the tunneling current was fixed at (a) 3 nA and (b) 2 nA. c, The moiré superlattice periodicity of ML-MoS₂/HOPG and the MoS₂ lattice expansion (green and orange diamonds) are derived from analyzing the FFT graphs and show an excellent match to the in-plane MoS₂ lattice expansion theoretical model (dashed curve). The top axis shows the lattice expansion in percentage. d, Schematic side-views of ML-MoS₂ on either a rigid SiO₂/Si substrate or a buffered h-BN/SiO₂/Si substrate and the resulting respectively asymmetric and symmetric rippling effects on the top and bottom sulfur layers. e, A proposed model of asymmetric lattice expansion in ML-MoS₂ on SiO₂/Si for T<T_{C} and under an out-of-plane external magnetic field, leading to broken mirror symmetry that give rises to the out-of-plane polar order.

FIGS. 5a-5h|Spectroscopic and electrical characterizations of the monolayer MoS₂ field-effect transistor (FET). a, Optical microscope image of a monolayer MoS₂ device #4. b, Typical Raman point spectrum showing the peak position of E_{2g} at 387 cm⁻¹, A_{1g} at 404 cm⁻¹, and a peak separation of ˜17 cm⁻¹. c, Typical photoluminescence (PL) point spectrum presenting an optical bandgap of ˜1.81 eV. d, PL intensity mapping, indicating a uniform monolayer structure. e,f, Scanning photoelectron microscopy (SPEM) spectra revealing the binding energy of Mo 3d and S 2p, respectively. All spectroscopic measurements were performed at T=300 K. g,h, I_{DS}-vs.-V_{DS} curves under various V_{GS} measured at (g) T=300 K and (h) 1.8 K, respectively on device #1. Insets present logarithmic I_{DS}-vs.-V_{GS} curves.

FIGS. 6a-6d|Low contact barrier ML-MoS₂ FETs down to 1.8 K. a, Main panel: Contact barrier extracted from Device #1 and Device #5 at 1.8 K. The arrows point to the dashed linear fits consistent with the flat-band conditions for ohmic contacts^{3,4}. While both devices exhibited a negligible contact barrier, the high temperature dependence of Device #5 exhibited a signature linear behavior in Arrhenius plot (inset), where electron injection originated from thermionic emission across a Schottky barrier. Here V_{GS} is colored from 6 V (red) to 20 V (blue) with an interval of 2V. b, Arrhenius plots of Device #1 measured between 100 K-300 K with V_{DS}=−0.6 V (main panel) and 1.8 K-10 K (inset) with V_{DS}=−2 V. Here V_{GS} is colored from 12 V (red) to 20 V (blue) with an interval of 1 V. The almost saturated slope indicates a vanishing contact barrier. Similar behavior is observed on Device #2 and Device #3. c,d, I_{DS}-vs.-V_{GS} characteristics of Device #1 under different V_{DS} values at 300 K and 1.8 K, respectively. For all devices except Device #5, the contact resistance exhibited nearly ohmic behavior at all temperatures.

FIGS. 7a-7b|V_{DS}-independent hysteresis loop size. a, I_{DS}-vs.-V_{GS} hysteresis curves measured under a magnetic field of −9 T with V_{DS} fixed at 1 V, 0.8 V, 0.6 V and −2V, respectively. b, Extracted V_{HW} (green) and ΔVₜₕ (|I_{DS}|=10 nA) (red).

FIG. 8|Frequency response of the hysteresis window. The extracted V_{HW} measured at a different V_{GS} sweep rate, each measured four times in a consecutive manner. V_{GS} range is 2-24 Volts while the sweep rate varies by a combination of voltage step and interval time between voltage steps. The measurement was taken at B=9 T, T=1.8 K and V_{DS}=2V on Device #1.

FIGS. 9a-9f|Consistent high and low-field hysteresis behavior measured on additional devices. a, Main panel: |I_{DS}|-vs.-V_{GS} hysteresis under magnetic field from 9 T to −9 T (sweep direction indicated by the black arrow) with V_{DS}=0.4 V measured on Device #3. A magnetic field sign-symmetry under B=±9 T is presented within experimental error as shown in the semi-log inset. b, Magnetic field-controlled V_{HW} extracted from (a). c, Threshold gate voltages V_{th,H} and V_{th,L} for Device #3 are shown as a function of the applied magnetic field from −9 T to 9 T. d, Main panel: |I_{DS}|-vs.-V_{GS} hysteresis loops under low magnetic fields from B=−0.5 T to 0.5 T (sweep direction indicated by the black arrow) with V_{DS}=0.6 V measured on Device #2 are shown for the sake of clarity. A magnetic field sign-symmetric low-field hysteresis behavior under B=±0.5 T is presented in the semi-log inset. e, Magnetic field controlled V_{HW} extracted from (d). f, Threshold gate voltages V_{th,H} and V_{th,L} for Device #2 are shown as a function of the applied magnetic field from −1.0 T to 1.0 T.

FIG. 10|Magnetoresistance measured on Dev. #5 at 1.8 K. The was obtained by sweeping the gate voltage up to 20 V at B=0 T with V_{DS}=−2 V and hold for 10 minutes. Then magnetic field was ramped (10 mT/s) to the positive maximum of 14 T followed by negative maximum of −14 T then zero, finishing one cycle. Four consecutive magnetic field ramping cycle was tested and no significant hysteresis was seen. The data was then averaged and shown.

FIGS. 11a-11b|Magnetic field sign-symmetric hysteretic behavior of the monolayer MoS₂ FET devices. a, |I_{DS}|-vs.-V_{GS} hysteresis under magnetic field from −9 T to 9 T (sweep direction indicated by the black arrow) with V_{DS}=−1 V measured after FIG. 1c. A magnetic field sign-symmetry under B=+9 T is presented within experimental error as shown in the semi-log inset. b, Magnetic-field controlled V_{HW} and extracted from (a) and FIG. 1c. Red and green arrows indicate the corresponding field ramping directions. These results strongly suggest the absence of any discernible out-of-plane magnetization.

FIGS. 12a-12b|Magnetic field-independent clockwise hysteresis at 260 K. a, |I_{DS}|-vs.-V_{GS} hysteresis under magnetic field from 9 T to −9 T with V_{DS}=−1 V measured at 260 K. As exemplified in the semi-log inset, clockwise hysteresis loop (indicated by black arrow) that was almost independent of magnetic field was observed under B=0 and B=−9 T. b, V_{HW}-vs.-B taken at 1.8 K, 14 K, 21 K and 260 K. Grey dashed line shows the constant zero V_{HW}.

FIGS. 13a-13c|Consistent temperature-dependent behavior on additional devices. a, Temperature dependence of V_{HW} under different magnetic fields from Device #2. b, Temperature dependence of ΔVₜₕ (|I_{DS}|=10 nA) under different magnetic fields from Device #5. c, Magnetic field-dependent T_{C} values for Devices #1, #2, #3 and #5. All T_{C} values were measured under positive magnetic fields except Device #3 where the T_{C} value was measured at B=−9 T.

FIGS. 14a-14b|Temperature-dependent Raman spectra and extracted shifts of the Raman modes. a, Temperature dependence of the monolayer MoS₂ and Si-substrate Raman spectra from T=300 K to 4.2 K. b, Extracted temperature dependence of the Si (dot), A_{1g} (square) and E_{2g} (triangle) Raman peak positions. The green dashed lines are fitted based on 100 K to 300 K data

FIGS. 15a-15h|Bias voltage-dependent moiré patterns. a-f, Reconstructed moiré superlattice topography and their filtered FFT images measured under a bias voltage of −1 V (a,b), −0.1 V (c,d) and 0.1 V (e,f), respectively. g,h, Measured topography of MoS₂ at a bias voltage of 0.7 V, showing mainly top sulfur atoms of MoS₂

FIGS. 16a-16h|Image processing and raw data of STM topography. a, Raw data of ML-MoS₂/HOPG moiré superlattice topography under a magnetic field of 5T. b, FFT image of the topography shown in (a), where blue and red circles highlighted the MoS₂ reciprocal lattice vectors and the moiré reciprocal superlattice vectors, respectively. Red, blue, and green arrows on the side are exaggerated illustrations of the reciprocal lattice vectors of the moiré superlattice, MoS₂ lattice and HOPG lattice, respectively, where the twisted angle was measured between the MoS₂ and HOPG reciprocal lattice vectors. c, Filtered FFT image. d, Topography reconstructed from the inverse FFT on (c). e,f, Raw data of moiré superlattice topography (e) and FFT image (f) measured under B=3 T. g,h, Raw data of moiré superlattice topography (g) and FFT image (h) measured under B=0.5 T. Here we note that the other signal points that were present in the raw data of FFT images of (b), (f) and (h) but were filtered out in our analyses originated from the increased scanning signal resolution in STM after applying a strong magnetic field, which not only enhanced the brightness of each lattice point in reciprocal space, but also made new convolution signals extending outward from lattice points more apparent. Therefore, the extra points extending outward from the MoS₂ periodic reciprocal space vector correspond to the MoS₂ convolution signals, and the extra points extending from the blue outer ring of the moiré periodic reciprocal space vector corresponding to the moiré convolution signals.

FIGS. 17a-17b|Low temperature piezo-response force microscopy (PFM) measurements of ML-MoS₂ at different magnetic fields. a, b, The amplitude of the PFM (represented by a blue circle and blue line) and the phase (indicated by a red square and red line), measured at B=0 and B=3 T, respectively.

FIG. 18|Schematic of the band alignment of Si/SiO₂/MoS₂ based on KPFM measurement for device #5.

FIGS. 19a-19b|STM topography of typical sulfur vacancies on MoS₂. a, Surface topography (20 nm×20 nm) with bias voltage −1 V, tunneling current 2.0 nA, and B=0, where the defect density is 5.0×10¹² cm⁻². b, One instance of a sulfur vacancy marked by red circle observed under B=5 T at 4.5 K with bias voltage of −0.4V and tunneling current of 2.0 nA.

FIGS. 20a-20d|Magnetic field-independent clockwise hysteresis at 1.8 K for h-BN buffered devices. a, |I_{DS}|-vs.-V_{GS} hysteresis under magnetic field from 9 T to −9 T with V_{DS}=−1 V measured at 1.8 K. As exemplified in the semi-log inset, clockwise hysteresis loop (indicated by black arrow) that was almost independent of magnetic field was observed under B=9 and B=−9 T. b, V_{HW}-vs.-B taken from (a), showing that the negative value of V_{HW} for clockwise hysteresis is independent of magnetic field. c, |I_{DS}|-vs.-V_{GS} hysteresis under magnetic field from 0 T to −9 T with V_{DS}=−2 V measured at 4 K. As exemplified in the semi-log inset, clockwise hysteresis loop (indicated by black arrow) that was almost independent of magnetic field was observed under B=0 and B=−9 T. d, V_{HW}-vs.-B taken from (c), showing that the negative value of V_{HW} is independent of magnetic field except for the first few starting cycles at B=0.

FIG. 21a-21d. MD simulations for the strain induced by a nano-tetrahedron: a, Schematic cross-sectional view of a tetrahedral gold nanoparticle with rounded top radius r=0.3 nm. b, Cross-sectional view of the final TMD equilibrium state. Here the orange line marked the plane where the imaginary gold substrate was created. c, Surface topography of the final equilibrium state. d, Spatial distribution of the strain tensor components eₓₓ, e_{yy} and e_{xy} (from left to right) in each of the three atomic layers (from top to down, upper S-layer, middle Mo-layer, bottom S-layer) in a monolayer MoS₂ with a rotation angle of 0° relative to the zigzag direction of MoS₂. Here we note strong spatial variations in the strain tensors over nanometer scales induced by the round-top nano-tetrahedron. FIG. 21e. Schematic of a FET on a strain engineered substrate.

FIGS. 22a-22d Topological photonic excitations on the magnetic field-induced ferroelectricity: FIG. 22a, Effects of 532 nm polarized light (righthanded/lefthanded circularly polarized light, RCP/LCP light; and linearly polarized light, LP light) on the |I_{SD}|-vs.-V_{G} hysteresis loops under B=9T at 1.8 K, showing excess photocurrents and suppression of ferroelectricity. FIG. 22b, Effects of 650 nm polarized light (RCP, LCP and LP light) on the |I_{SD}|-vs.-V_{G} hysteresis loop under B=9T at 1.8 K, showing suppressed ferroelectricity but no excess photocurrents (relative to the “dark” loop). Here the excitation energy of light equals the direct bandgap of SL-MoS₂. FIG. 22c, Effects of topological charge l of 650 nm OAM light on the field-induced |I_{SD}|-vs.-V_{G} hysteresis loop under B=9 T at 1.8 K, showing increasing asymmetric behavior between l and −l OAM light. FIG. 22d, Optical micrograph of a SL-MoS₂ FET device, showing the alignment of the source(S) and drain (D) contacts (gold) on a monolayer MoS₂ (dark green, triangular shape) relative to the positive OAM light (l>0).

FIG. 23. Flowchart illustrating a method of making a device.

FIG. 24. Flowchart illustrating a method of using a device.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized, and structural changes may be made without departing from the scope of the present invention.

### Technical Description

### First Embodiment: Ferroelectric Response Using Rigid Substrates and Applied Magnetic Field

### 1. Device Structure

In one embodiment, giant ferroelectric-like hysteresis is induced by out-of-plane magnetic field (B) applied to a field-effect transistors (FETs) comprising a monolayer (ML) MoS₂ single crystals on SiO₂/Si substrates at temperatures (T) below ˜20 K.

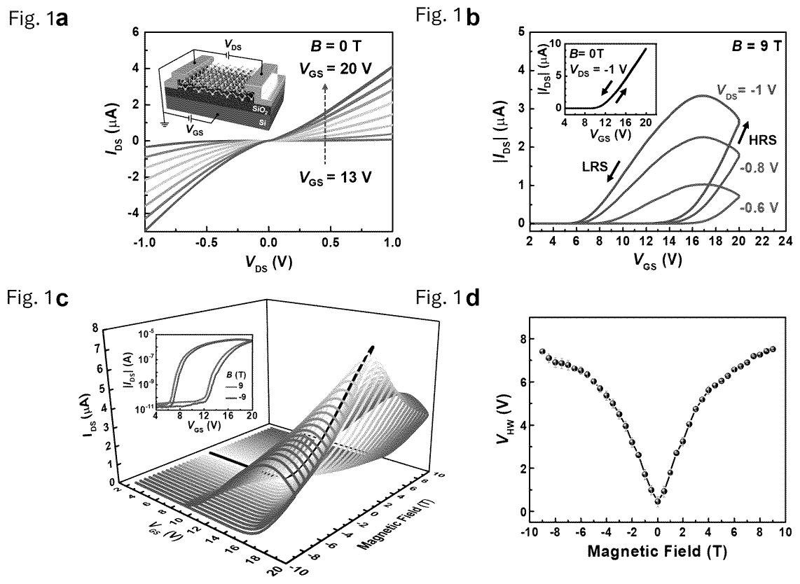

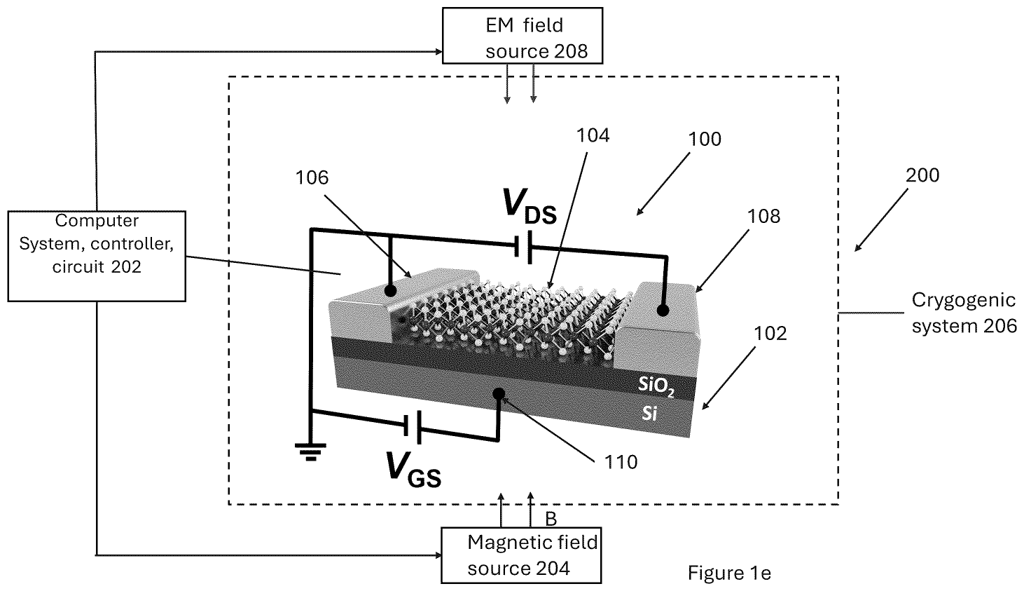

FIG. 1 illustrates the FET comprises a substrate; a monolayer of a single crystal semiconducting transition metal dichalcogenide (TMD) on the substrate; a source contact and a drain contact to the monolayer; and a gate contact on the substrate; wherein the a gate voltage applied to the gate contact with respect to the source contact modulates the ferroelectric response of the monolayer when an external magnetic field and a gate voltage is applied perpendicular to the surface of the monolayer and a current through the monolayer between the source contact and the drain contact. The substrate is rigid and the monolayer experiences asymmetric lattice expansion against the rigid substrate in response to an external magnetic field perpendicular to a surface of the monolayer and when cooled below 20 degrees Kelvin.

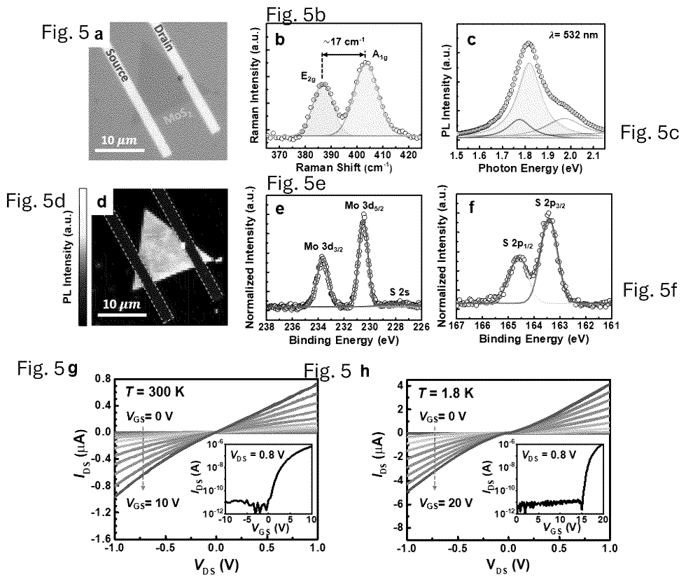

The source-drain voltage (V_{DS}) was applied between a pair of bismuth (Bi)/gold (Au) contacts, and the gate voltage (V_{GS}) was applied between the source contact and a heavily p-doped Si substrate with a 30 nm-thick SiO₂ insulating layer. The 1H—MoS₂ single crystals (a.k.a. ML-MoS₂ with the 2H-phase) grown by chemical vapor deposition (CVD)²²⁻²⁴ exhibited high degrees of homogeneity after fabrication, as verified by their optical spectroscopic characterizations exemplified in FIG. 5.

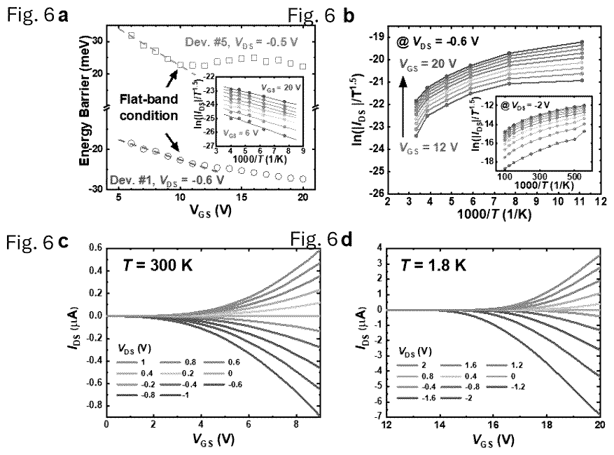

Additionally, nearly ohmic source-drain current (I_{DS}) versus gate voltage (V_{GS}) transfer curves were observed down to 1.8 K (FIG. 1a,) due to ultralow-barrier Bi/Au contacts²⁵ (Methods, FIGS. 5 and 6, Notes 1,2).

The counterclockwise hysteresis of the source-drain current (I_{DS}) as a function of the back-gate voltage (V_{GS}) can be enhanced by increasing the maximum V_{GS} value, increasing |B|, and lowering T. These findings differ drastically from previous reports of high-temperature and zero-B hysteretic behavior in ML-MoS₂ FETs, which have been attributed to mechanisms such as thermally-activated trapped states¹⁸⁻²⁰, absorbates^{4,5}, and ordinary gate voltage-induced stress effects²¹, where clockwise hysteresis loops were observed near room temperatures without magnetic field dependences.

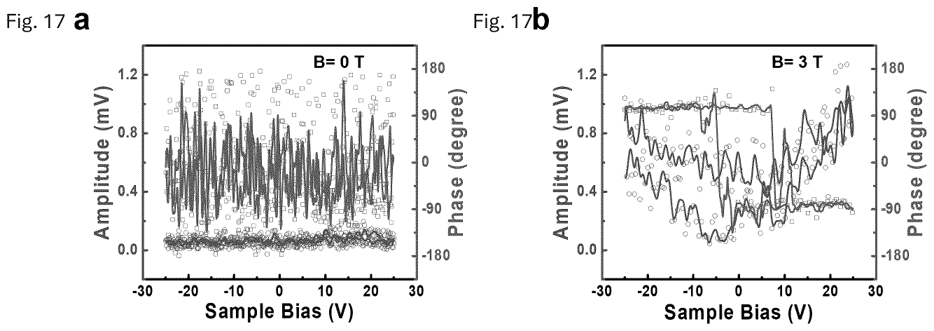

The hysteresis in the source drain current is associated with the ferroelectric response of the device after confirmation that the monolayer is indeed ferroelectric by measuring hysteresis in the polarization as a function of applied electric field (e.g., generated by applying the gate voltage across the monolayer). More specifically, piezo-response force microscopy was used to measure ferroelectric response by observing a polarization loop under the same magnetic field conditions (see FIG. 17).

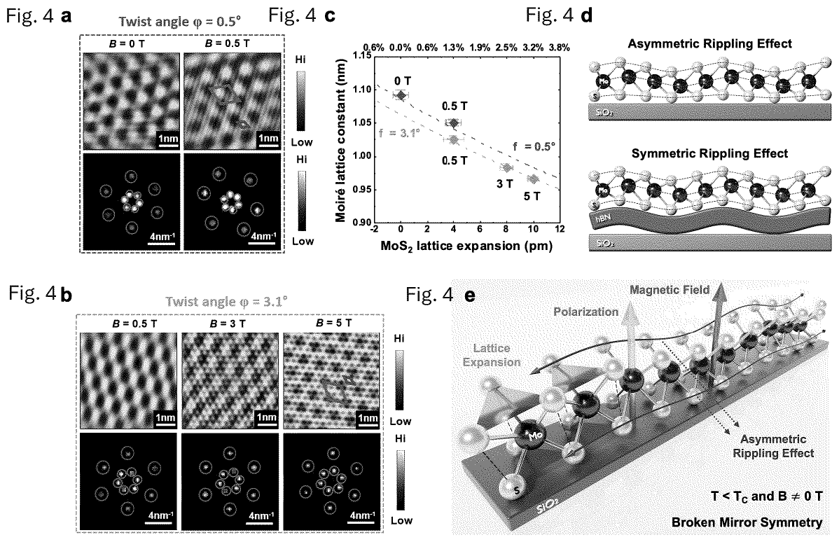

Scanning Tunneling Microscopy (STM) measurements of the monolayer on a conducting substrate (consisting of a piece of highly oriented pyrolytic graphite, HOPG) confirmed the ferroelectric response is associated with lattice expansion induced by the magnetic field (in all directions and in plane and out of plane), which was also corroborated using Raman spectroscopy. This expansion becomes asymmetric when the monolayer MoS₂ is placed on a rigid substrate like SiO₂/Si so that the top and bottom layers of dichalcogenide expanding differently, which is in contrast to the situation of placing monolayer MoS₂ on another van der Waals material like HOPG or hexagonal boron nitride (h-BN) that would accommodate the lattice expansion of monolayer MoS₂, as schematically illustrated in FIGS. 4d-e.

Further information on the characterization is discussed in the following sections.

### 2. Characterization of Emerging Electric Hysteretic in MoS₂-FETs

Under an out-of-plane magnetic field (B), counterclockwise |I_{DS}|-vs.-V_{GS} hysteretic loops emerged from measurements of the FET devices at 1.8 K, as exemplified in FIG. 1b for B=9 T, where the |I_{DS}|-vs.-V_{GS} transfer curves were measured with different V_{DS} values fixed at −1.0 V, −0.8 V, and −0.6 V. On the other hand, no loop was present for B=0 (FIG. 1b inset). This emergence of counterclockwise hysteretic behavior at low temperature and finite magnetic field is a response of polar order modulation, which is different from previously known hysteresis-inducing mechanisms (Note 3).

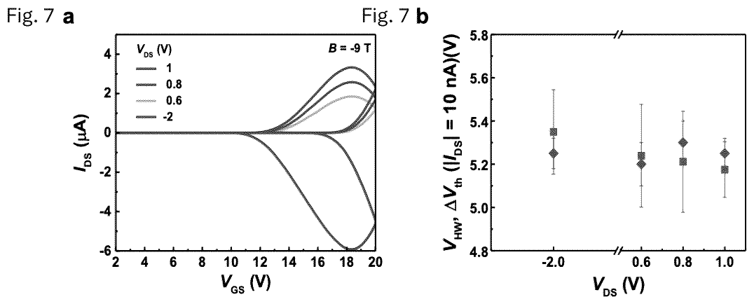

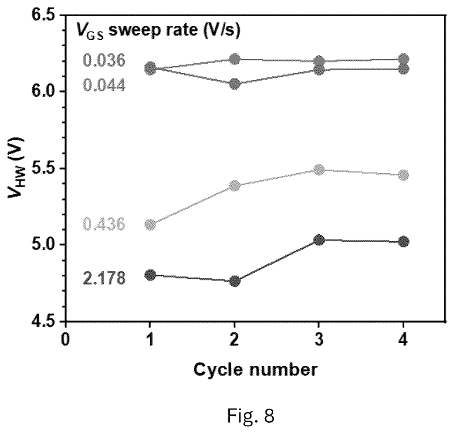

When sweeping up V_{GS}, the system was initially in the high-resistance state (HRS)²⁶, showing |I_{DS}|>0 for V_{GS}>V_{th,H}, where V_{th,H} denoted the threshold voltage for the forward branch defined in Methods. In contrast, when V_{GS} was reduced from a finite |I_{DS}| state, the lattice returned from a highly polarized low-resistance state (LRS)^{7,26} so that |I_{DS}| remained finite until V_{GS} reached V_{th,L} (<V_{th,H}), where V_{th,L} represented the threshold voltage for |I_{DS}|>0 in the returned branch. Within the applicable range of V_{GS} up to 36 V in all devices (Dev. #1-#5), none of the hysteresis loops became fully closed within our experimental parameters due to limited gating range and the necessity of keeping the leakage current small (Methods). We found that |I_{DS}| continued to increase upon reversing V_{GS} from 20 V to 16 V (FIG. 1b), which may be due to the transient response of charging as a result of polar order modulation. Additionally, while the |I_{DS}|-vs.-V_{GS} curves measured with different V_{DS} values yielded different loop shapes, the extracted hysteresis window V_{HW} (≡V_{th,H}−V_{th,L}) remained the same (FIGS. 7 and 8, Note 4). The independence of V_{HW} on the in-plane voltage V_{DS} suggested that the field-induced polarization was mostly tunable via the out-of-plane electric field. Further studies of the |I_{DS}|-vs.-V_{GS} curves for different B values under a constant V_{DS}=−1.0 V are shown in FIG. 1c for one of the devices.

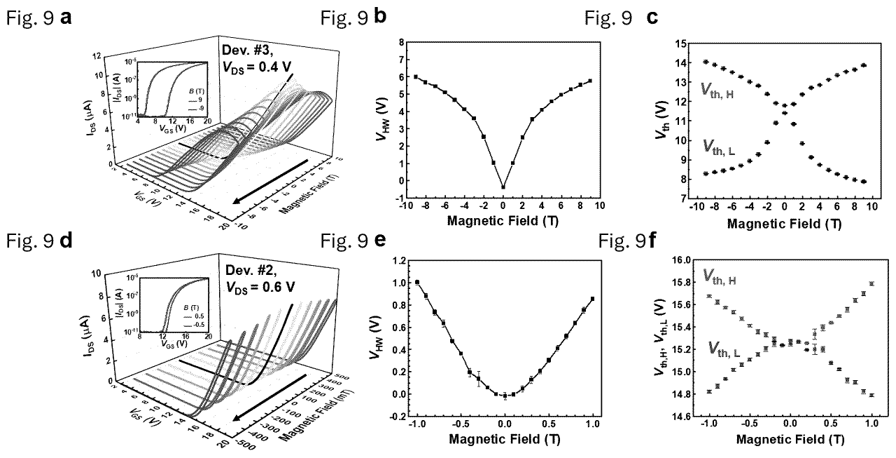

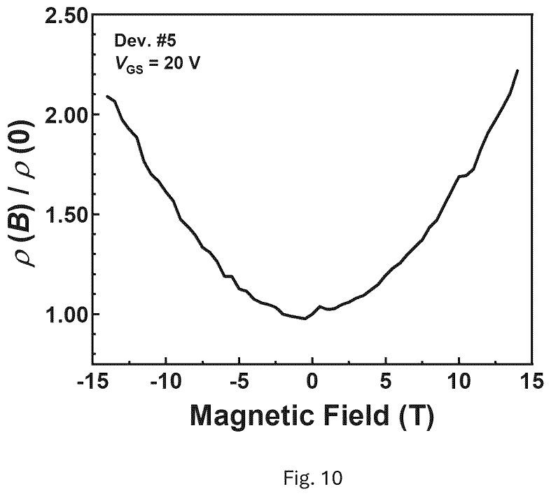

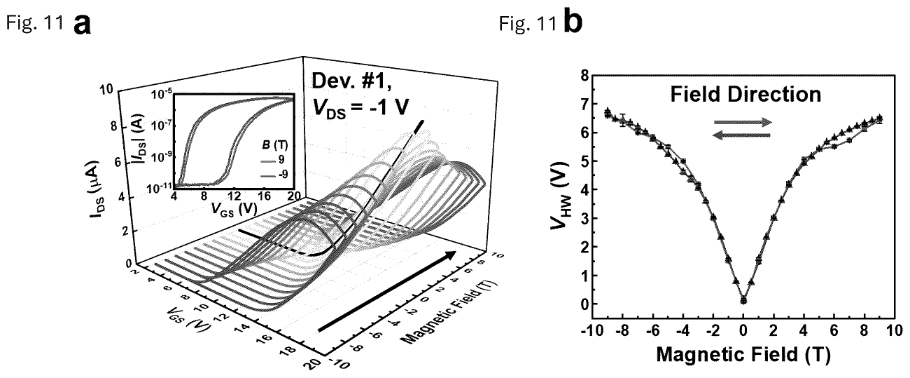

Overall, the following key findings were consistently observed across five different devices (FIG. 9, Note 5): (1) under a constant out-of-plane B, the |I_{DS}| value obtained at a given V_{GS} was smaller for a larger |B| due to a positive magnetoresistance (FIG. 10); (2) the size of the hysteresis loop V_{HW} increased with |B|; (3) the hysteresis loop was independent of the sign of B from −9 T to 9 T (FIG. 1c); (4) no discernible magneto-hysteresis of |I_{DS}|-vs.-V_{GS} curves was observed during the two consecutive magnetic field sweeps from −9 T to 9 T then from 9 T back to −9 T (FIG. 11); and (5) the hysteresis window V_{HW} increased approximately linearly with |B| for |B|<3 T, and then saturated for large |B| (FIG. 1d).

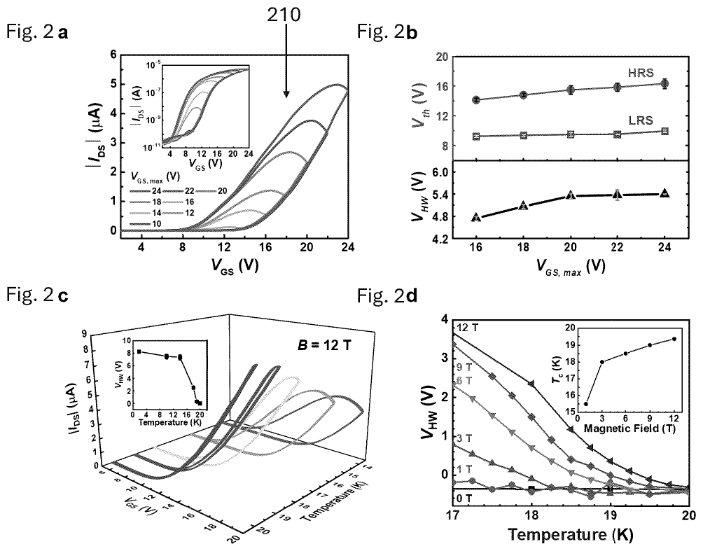

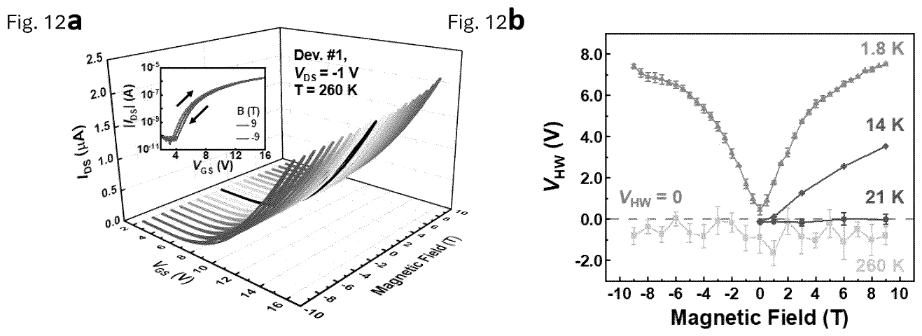

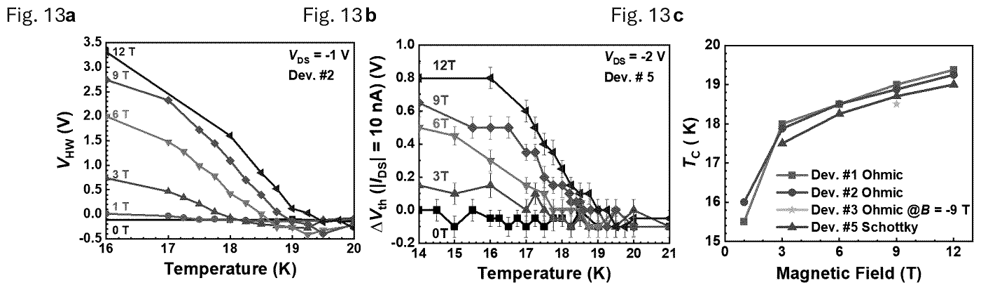

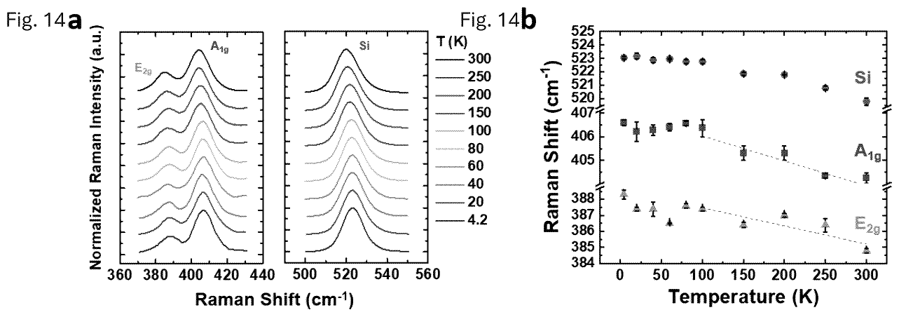

In addition to magnetic field, gate voltage and temperature may be used to modulate this hysteresis, although less significant than the magnetic field. FIG. 2a shows the linear and semi-log scale (inset) |I_{DS}|-vs.-V_{GS} curves of a FET device measured at 10 K and B=9 T and for V_{GS} swept from 2 V to different maximum gate voltages (V_{GS, max}) then back. Interestingly, under a fixed magnetic field, a higher V_{GS, max} led to increasing although eventually saturating V_{HW} (FIG. 2b). On the other hand, upon increasing temperature from 1.8 K under a constant magnetic field of 12 T, the size of the hysteresis loop first shrank gradually with temperature, and then decreased precipitously above ˜14 K, and finally vanished at the critical temperature (T_{C})˜19.3 K (FIG. 2c) where V_{HW} vanished completely (FIG. 2c, inset). Above the T_{C}, a small magnetic field-independent clockwise hysteresis background emerged as exemplified in FIG. 12 and described in Note 6, which was due to the gate voltage stress²¹ and remnant oxide trapping close to the SiO₂—MoS₂ interface as previously reported^{18,19}. We further investigated the temperature dependence of V_{HW} for the counterclockwise hysteresis loops under different constant magnetic fields (FIG. 2d) and found that the critical temperature T_{C} where V_{HW} vanished increased with increasing |B| (FIG. 2d, inset), whereas for a given temperature below T_{C}, V_{HW} always increased with |B|. The modulation of T_{C} by magnetic field may be understood by considering the frozen of in-plane TA and LA phonon modes below 20 K²⁷, where the magnetic field induced lattice expansion emerged and was less disturbed by in-plane phonons. Therefore, larger degrees of lattice expansion induced by stronger magnetic field may survive a higher temperature so that a higher T_{C} was observed. Overall, comparable T_{C}-vs.-B values within ±1 K variations among four different devices were found (FIG. 13, Note 7), suggesting the robust presence of this hysteresis across devices.

### 3. Characterization of Magnetic Field Induced MoS₂ Lattice Expansion

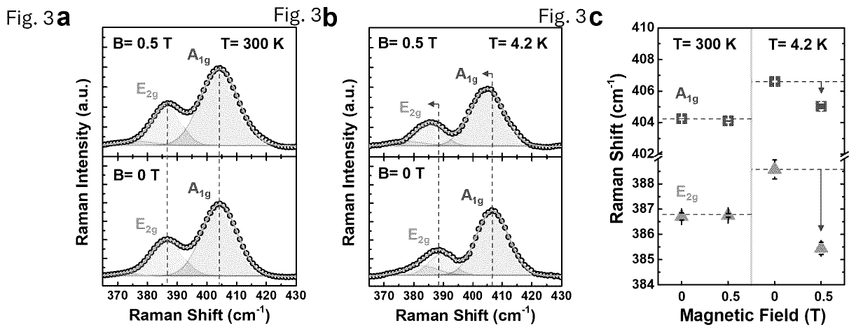

To elucidate the physical origin for magnetic field-induced hysteresis in these ML-MoS₂ FETs, we carried out cryo-temperature Raman spectroscopic studies of ML-MoS₂ on silicon substrates, as shown in FIGS. 3 a,b. Upon cooling the sample from 300 K at B=0, both the A_{1g} and E_{2g} peaks were found blue-shifted due to a positive thermal expansion coefficient (TEC) down to ˜20 K, below which the TEC became slightly negative as a result of frozen of in-plane phonon²⁷⁻²⁹ (FIG. 3c, Note 8). In particular, the peak positions of the A_{1g} and E_{2g} modes at 4.2 K were found to be at 406.6 cm⁻¹ and 388.6 cm⁻¹, respectively, both higher than the A_{1g} (404.3 cm⁻¹) and E_{2g} (386.7 cm⁻¹) peak positions measured at 300 K. Upon the application of an out-of-plane magnetic field of 0.5 T, however, significant field-induced redshifts were found for both the E_{2g} (−3.1 cm⁻¹) and A_{1g} (−1.5 cm⁻¹) modes at 4.2 K, whereas no discernible field-induced effect on the Raman modes was observed at 300 K, as shown in FIG. 3c. These findings suggest that under a magnetic field below T_{C}, both the in-plane E_{2g} mode and the out-of-plane A_{1g} mode became softened, which implied a tensile strain on the lattice, similar to the Raman mode softening observed in the bubbled regions of ML-WS₂ encapsulated by h-BN³⁰.

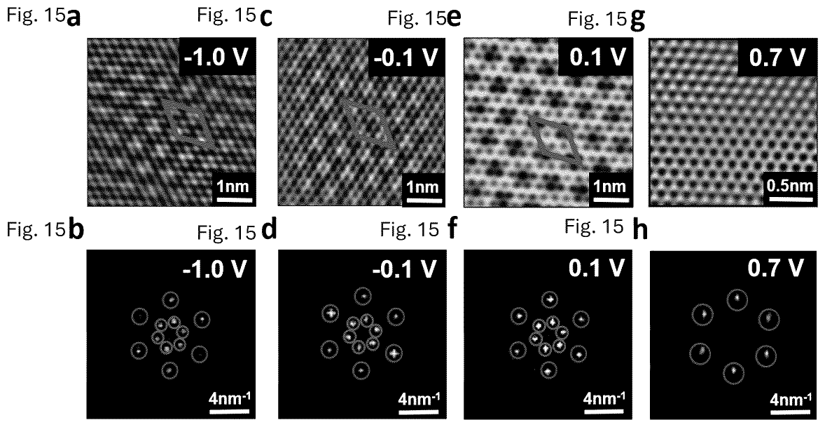

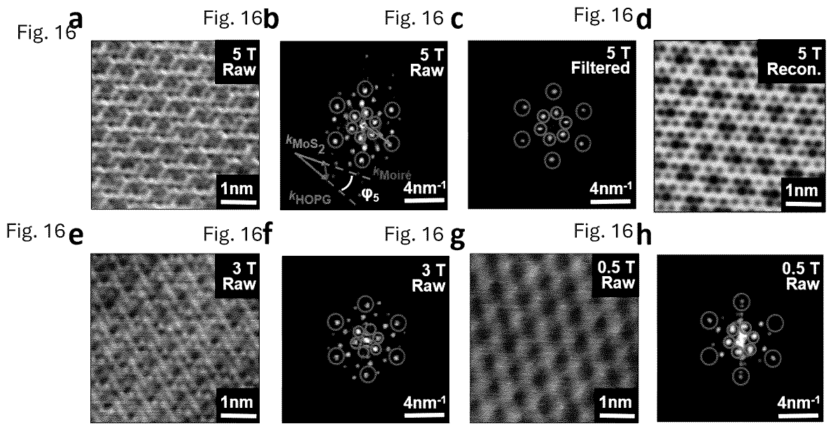

Further evidence for magnetic field-induced lattice expansion was manifested by scanning tunneling microscopic (STM) studies of a ML-MoS₂ sample grown in situ on highly ordered pyrolytic graphite (HOPG). The filtered ML-MoS₂/HOPG topographic images (Methods, FIGS. 15 and 16, Note 9) showed evolving moiré patterns with magnetic field for two distinct (5 nm×5 nm) regions with a twist angle (φ) of 0.5° (FIG. 4a) and 3.1° (FIG. 4b) at B=0, respectively. The corresponding reciprocal lattice points for the moiré pattern and ML-MoS₂ were respectively highlighted in red and blue circles in the Fast Fourier transformation (FFT) graphs of the topography, as shown in the bottom panels of FIGS. 4a,b. With increasing B, a systematically increasing ML-MoS₂ lattice constant as well as a decreasing moiré lattice constant were found from analyzing the reciprocal lattice vectors in the corresponding FFT graphs taken over the same (5 nm×5 nm) area, whereas the HOPG lattice constant remained the same³¹. As shown in FIG. 4c, we found ˜3% in-plane lattice expansion for B=5 T and ˜1.3% in-plane lattice expansion for B=0.5 T, the latter agreed well with the estimate of ˜1.4% lattice expansion from the redshift of the E_{2g} Raman mode^{32,33}. These results thus provide solid evidence for substantial magnetic field-induced lattice expansion in ML-MoS₂ at low temperature. Moreover, the expected A_{1g} shift from the pure tensile strain of 1.4% would have been about −0.8 cm⁻¹ predicted by first principle calculations and previous experiments^{32,33}, yet −1.5 cm⁻¹ was observed in our Raman measurement as shown in FIG. 3c. This difference may be understood by noting that the peak position of the out-of-plane A_{1g} phonon mode is much more sensitive to charge accumulation than the in-plane E_{2g} mode³³, so that the larger redshift found in the A_{1g} mode may be attributed to the presence of net out-of-plane charge distributions³⁴ and thus supports the occurrence of spontaneous out-of-plane polarization.

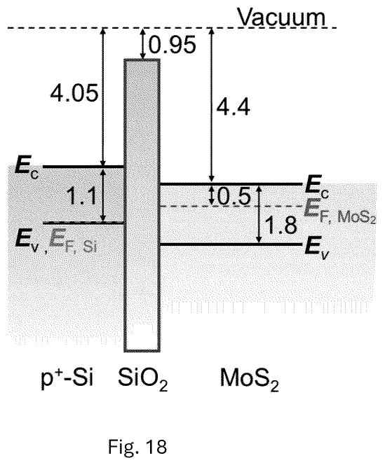

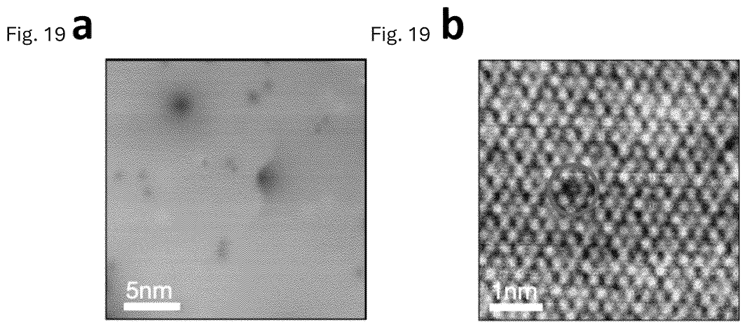

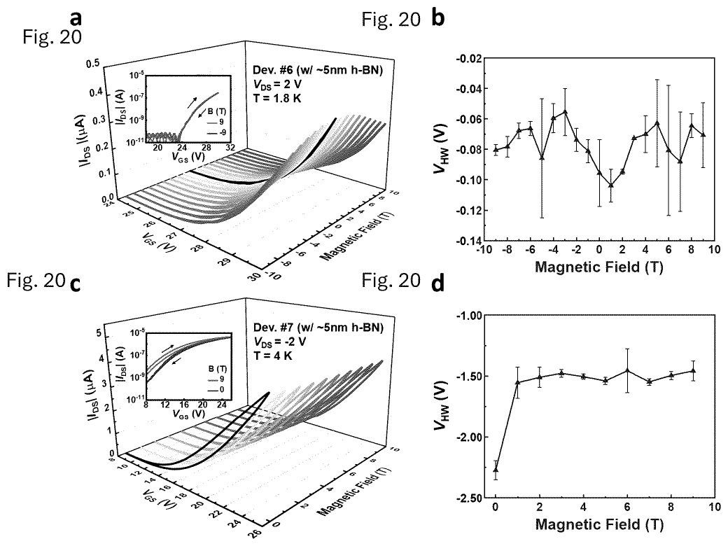

A plausible explanation for our observation of magnetic field-induced giant hysteretic behavior is due to a bistable ferroelectric-like spontaneous out-of-plane polarization, which emerges under anisotropic lattice expansion-induced flexoelectric effect³⁵ due to the TEC mismatch between ML-MoS₂ and the underlying rigid SiO₂/Si substrate^{27,3536}, as shown in FIGS. 4d,e. Further supporting evidence for this scenario was provided by piezo-response force microscopy (PFM) measurements, which revealed evident ferroelectric butterfly hysteresis loop emerged at 1.6 K and B=3 T whereas no piezoelectric response was found at B=0, as exemplified in FIG. 17 (Note 10). This finding indicated that the flexo-induced out-of-plane polar order under a finite out-of-plane magnetic field was switchable by a nonlinear electric field applied by a PFM³⁵. Other than anisotropic flexo-induced polarization incurred by the underlying rigid substrate and MoS₂ rippling, local charge disorder due to sulfur vacancies may also contribute to the nonlinear effect found in the PFM measurements. However, we believe that the low sulfur vacancy concentration (˜0.2%) in our ML-MoS₂ samples (FIGS. 18 and 19, Note 11) and the tendency of reduced tensile strain loading with increasing vacancy concentration as the result of decreasing Young's modulus³⁷ would have diminished the flexoelectric effect. The important role of the substrate in the occurrence of out-of-plane anisotropic lattice expansion and the accompanying polar effect was further verified by studying two ML-MoS₂ FETs buffered by ˜5 nm thick hexagonal boron nitride (h-BN) between the ML-MoS₂ and the rigid SiO₂/Si substrate. Both buffered FETs revealed no obvious magnetic field-induced counterclockwise hysteresis (FIG. 20), which was expected because the h-BN buffer had a similar negative TEC³⁸ and also exhibited low lateral friction³⁹ relative to the MoS₂ layer so that the centrosymmetry-breaking required for ferroelectric-like polarization was largely prevented in the buffered ML-MoS₂ FETs on h-BN/SiO₂/Si substrates (Note 12). The relevance of the substrate to the occurrence of out-of-plane polar order in ML-MoS₂ is schematically illustrated in FIG. 4d, where the side-views for the asymmetric and symmetric rippling effects between the top and bottom sulfur layers are shown for ML-MoS₂ on SiO₂/Si and h-BN/SiO₂/Si substrates, respectively. Our proposed model of asymmetric lattice expansion between the top and bottom sulfur layers of ML-MoS₂ on SiO₂/Si below T_{C} and under an out-of-plane external magnetic field is further illustrated in FIG. 4e, showing the occurrence of broken mirror symmetry.

Overall, our experimental findings from five distinct FET devices of ML-MoS₂ on SiO₂/Si suggested that the out-of-plane magnetic field-induced ferroelectric-like counterclockwise hysteresis was robust at low temperature and reversible upon removing the magnetic field, and the absence of such phenomena in two buffered FET devices of ML-MoS₂ on h-BN/SiO₂/Si further accentuated the important role of substrates in inducing the anisotropic magnetic field-induced lattice expansion, which was essential for the out-of-plane electric polarization. The magnetic field-induced lattice expansion in ML-MoS₂ at low temperatures is likely associated with the occurrence of a magnetic field-induced structural phase transformation, although the microscopic mechanism and the nature of this phase transformation remain unclear. A possibility may be related to lifting the valley degeneracy in ML-MoS₂ by magnetic field due to strong spin-valley coupling, thereby resulting in a real-space structural transformation. Additionally, the correlation between the size of hysteresis (V_{HW}) and the magnitude of out-of-plane magnetic field (|B|) is suggestive of multiferroic-like behavior. Overall, a careful ab initio calculation that takes into consideration of the effects of magnetic field, temperature, sulfur vacancies, and substrate will be necessary to fully account for our observation and to unravel the underlying physical mechanism, which is beyond the current scope of our work. Regardless of the microscopic physical origin, the giant magnetic-field induced ferroelectric-like responses in the ML-MoS₂ FET devices exhibited strong stability and reproducibility, thus promising for such technological applications as cryo-temperature ultracompact non-volatile memories, memtransistors, and ultrasensitive magnetic field sensors.

### 4. Supplementary Information on Device Fabrication Methods

Monolayer (ML) MoS₂ samples were synthesized on sapphire substrates by chemical vapor deposition (CVD)²²⁻²⁴. Standard PMMA-assisted wet transfer technique was used to transfer MoS₂ single crystals from sapphire substrates to standard Si/SiO₂ (90 nm oxide thickness) substrates using ammonia solution. PMMA residue and surface contamination was then removed by acetone/isopropanol, which was followed by N-methyl-2-pyrrolidone (NMP) solution. Electrical contacts consisting of 20 nm Bi and 50 nm Au were made by e-beam lithography and thermal evaporation.

### 5. Supplementary Information on Device Characterization

a. Methods

The electrical transport characterization of the devices was carried out using Physical Property Measurement System (PPMS) by Quantum Design in a vacuum (<10 mTorr) cryostat, which allowed a tunable temperature ranging from 1.8 K to 400 K and a maximum tunable magnetic field of ±14 T. The device was annealed at 400 K under vacuum overnight to remove possible water and oxygen adsorbates^{20,40}. All electrical transport measurements were conducted under the DC condition with the source-measuring units Keithley 2636B/2450. The gate voltage V_{GS} was kept below 24 V to ensure the leakage current staying below 0.1 nA, and the V_{GS} sweep rate of 0.044 V/s or slower was found to produce consistent hysteresis loops, hence the sweep rate of 0.044 V/s or slower was used for all hysteresis measurements unless otherwise specified.

The optical characterization of the MoS₂ devices was carried out under T=4.5 K ˜300 K temperature control with an out-of-plane magnetic field B up to ±0.5 T. A 532 nm continuous-wave laser was used as an excitation source, which was focused on the sample for optical characterization with a 50× objective lens (NA=0.5). The temperature-dependent and magnetic field-dependent Raman (1200 lines/mm) and PL (150 lines/mm) spectra were measured by a ANDOR Kymera 328i spectrometer.

The scanning tunneling microscopy (STM) studies were carried out on ML-MoS₂ samples, grown in situ by CVD on cleaved HOPG substrate, at a vacuum base pressure of 2×10⁻¹⁰ Torr (See Note 8). The topography measurements of the moiré superlattice patterns were obtained with a bias voltage of 0.7 V and a constant current of 2 nA.

b. Note 1: Basic Characterization of Devices

FIG. 5a presents an optical microscope image of one of our monolayer MoS₂ FETs. The monolayer 1H—MoS₂ sample in the fabricated device exhibited high degrees of homogeneity according to optical spectroscopic characterizations, including spatial maps of the photoluminescence (PL) and the A_{1g}-E_{2g} Raman peak separation under an excitation wavelength of 532 nm, as demonstrated in FIGS. 5c, e respectively. The representative single point spectra indicated a typical PL optical bandgap of ˜1.81 eV and the Raman peak separation between E_{2g} (˜387 cm⁻¹) and A_{1g} (˜404 cm⁻¹) of ˜17 cm⁻¹, as shown in FIGS. 5b, c respectively. The X-ray photoelectron spectroscopy (XPS) experiments, as exemplified in FIGS. 5e, f were carried out using the scanning photoelectron microscopy (SPEM) endstation at beamline 09A1 of the National Synchrotron Radiation Research Center's Taiwan Light Source at ultra-high vacuum (UHV) conditions of ˜10⁻⁹ Torr near 300 K, with a pre-annealing process of sample for 20 hours at ˜400K. Monochromatic soft X-rays (400 eV photon energy) were focused down to a ˜200 nm spot using Fresnel-zone-plate-based focusing optics and photoelectrons are collected. These spectral characteristics of our samples after the polymer-based device fabrication process were still consistent with the values obtained from direct measurements on high quality single crystalline monolayer MoS₂ samples reported previously^{1,2}.

Most FET devices studied in this work exhibited an ohmic-like low contact barrier behavior^{3,4} in the I_{DS}-vs.-V_{DS} curves from 300 K to 1.8 K under different V_{GS} values, as exemplified in FIG. 5g, h and detailed below. The insets of FIGS. 5g,h revealed an on/off ratio >10⁵, while a shift of threshold voltage from 0 V (300 K) to 15 V (1.8 K) was apparent due to fewer thermally excited carriers at low temperature.

c. Note 2: Ohmic-Like Low Contact-Barrier MoS₂ FET Device Characterization

Bi/Au contact is known for having low contact barrier and ohmic behavior down to 77 K⁴. Our study followed the same methodology and showed that our devices had an ohmic-like behavior at 300 K and a near-ohmic behavior at 1.8 K, as exemplified in FIG. 6. Under the condition that qV_{DS}>>k_{B}T, the thermally injected current from Bi/Au contact to our MoS₂ single crystal may be approximated by the following equation^{1,2}:

$${I}_{DS} \approx {A}_{2 D}^{*} {T}^{1.5} exp ( - \frac{{E}_{A}}{{k}_{B} T} ) ,$$

where A_{2D}*=q(8πk_{B}³m*/h²) is the Richardson constant for a 2D system, E_{A}=qϕ_{B} is the Schottky barrier height under the flat-band condition (FIG. 6a). The inset of FIG. 6a showed a typical device (Device #5) that exhibited a typical Schottky barrier-like behavior, with negative linear slopes in the Arrhenius plot. In contrast, ohmic-like contacts were found in Devices #1-#3 with extracted Schottky barrier of −20 meV, which exhibited positive slopes that asymptotically approached zero slope in the Arrhenius plot (FIG. 6b) as a signature of negligible contact barrier, similar to the report by Shen et. al.⁴. As a result, the device showed ohmic-like |I_{DS}|-vs.-V_{DS} transfer curves at 300 K (FIG. 5g) and nearly-ohmic transfer curves at 1.8 K (FIG. 5h). FIG. 7c,d showed corresponding I_{DS}-vs.-V_{GS} curve measured at 300 K and 1.8 K. To estimate the field-effect mobility of the FET devices, we used the following formula⁵:

$$μ = \frac{{dI}_{DS}}{{dV}_{GS}} \times \frac{L}{{WC}_{g} {V}_{DS}} ,$$

where C_{g}=ε₀εᵣ/d is the capacitance per unit area, εᵣ and d are the relative dielectric constant and the thickness of the SiO₂ layer, respectively. For a single-crystal device, the length to width ratio (L/W) was estimated to be ˜1.38 for Device #1 based on optical measurements. The mobility for Device #1 thus estimated ˜2 cm²V⁻¹S⁻¹ at 300 K and ˜7 cm²V⁻¹S⁻¹ at 1.8 K. This value is within range of previously reported mobility range between 0.1-10 cm²V⁻¹S⁻¹ over exfoliated ML-MoS₂ devices on typical Si/SiO₂ substrates⁵⁻⁷.

d. Supplementary Information on Extracting the Hysteresis Window V_{HW}

The threshold voltages V_{th, H} and V_{th,} L were extracted by first fitting the linear region of the HRS (forward branch) and LRS (backward branch) of the |I_{DS}|-vs.-V_{GS} transfer curves respectively, then finding their corresponding x-axis intercepts. The hysteresis window V_{HW} was then given by V_{HW}≡V_{th, H}−V_{th, L} and was largely independent of V_{DS}, as shown in FIG. 7. Another practical quantity to characterize the hysteresis loop size is the hysteresis width (ΔVₜₕ)²⁰, which is defined as the gate voltage difference between the intercepts of a small threshold current (i.e., 10 nA) with the HRS and LRS |I_{DS}|-vs.-V_{GS} curves so that ΔVₜₕ (|I_{DS}|=10 nA)≡V′_{th, H} (|I_{DS}|=10 nA)−V′_{th, L} (|I_{DS}|=10 nA). In our study, we found that both V_{HW} and ΔVₜₕ (|I_{DS}|=10 nA) gave similar results while the former was independent of the choice of the threshold quantity (threshold current), as exemplified in FIG. 7b. Therefore, we chose V_{HW} to represent to the size of the hysteresis loop unless otherwise specified. We further remark that the Zeeman splitting under external magnetic fields would reduce the bandgap at the K or K′ valley via lowering the conduction band minimum and lifting the valence band maximum. However, this effect was on the order of 10⁻³˜10⁻⁴ eV for |B|˜10 T^{41,42}, which corresponded to approximately 10⁻²˜10⁻³ V changes in the back gate voltage. Therefore, this effect was negligible in the process of extracting the threshold voltages.

e. Note 3: Discussion on Various Known Hysteresis-Inducing Mechanisms

We reviewed possible mechanisms that were previously identified in the literature and were fundamentally different from the hysteresis behavior that we observed in the |I_{DS}|-vs.-V_{GS} transfer curves reported in this work.

Firstly, our findings differ drastically from previous reports of high-temperature and zero-B hysteretic behavior in monolayer MoS₂-FETs, which have been attributed to mechanisms such as thermally-activated extrinsic or intrinsic trapped states⁸⁻¹⁰, absorbates^{11,12}, and gate voltage-induced stress effects¹³, where clockwise hysteresis loops were observed near room temperatures without magnetic field dependences. We have also observed similar gate voltage stress type of clockwise hysteresis at higher temperature above T_{C}, as detailed in Note 7.

At temperature below 4.2K, the presence of Schottky barrier between Cr/Au contact and MoS₂ can induce counterclockwise hysteresis in |I_{DS}|-vs.-V_{GS} transfer curves¹⁴. However, this type of hysteresis bears signature of a sharp rise in I_{DS} upon uncertain onset V_{GS} and the V_{HW} is larger with increasing V_{GS} sweep rates, contrary to our observations shown in FIG. 1. The Schottky barrier height in such devices is an result of a large Cr/Au contact barrier of ˜200 meV^{14,15}, whereas our devices shows negligible Schottky barrier height of +20 meV as shown in the FIG. 6a. Furthermore, our devices exhibited no abruptly changing counterclockwise hysteresis behavior at B=0. These contrasts all indicate that our magnetic field-induced counterclockwise hysteresis bears different physical origin from the Schottky barrier mechanism.

Sulfur vacancies that exist in all MoS₂ FETs, as we discussed in the manuscript, could induce shallow donor-like trap states¹⁶, deep trap states above the valence band maximum^{16,17}, or charge trapping at the oxide interfaces^{10,12}. However, all of which would have led to magnetic field-independent clockwise hysteresis at relatively high temperatures, which contradicted to our magnetic field-dependent counterclockwise hysteresis at cryo-temperatures. In-plane motion of sulfur vacancies has been shown to introduce in-plane ferroelectricity with counterclockwise hysteresis loops¹⁸. However, this scenario differs from our findings of negligible in-plane electric-field driven hysteresis and requires artificial creation of sulfur vacancies via focused ion beam. Finally, interlayer motion of sulfur vacancies would have been energetically too costly to occur at low temperatures. Thus, we may rule out vacancy-induced trap states as well as in-plane ferroelectricity as the cause of this magnetic-field induced hysteresis at cryo-temperatures.

Flexoelectric effect could also manifest themselves as counterclockwise hysteresis as a result of strain gradient¹⁹. However, such polarization relies on the strain gradient that is non-switchable, thus incompatible with our PFM results.

As for piezoelectric effect, it has been reported that the in-plane piezoelectric coefficient are much larger than the out-of-plane one^{19,20}, thus less likely being the cause for our findings of V_{HW} being mostly due to out-of-plane electric field and almost independent of the in-plane electric field.

In summary, we have ruled out all known mechanisms reported in the literature and thus demonstrated the novelty of our findings of magnetic field-induced hysteresis.

f. Note 4: Further Characterization of Hysteresis Window

As shown in FIG. 7a, the I_{DS}-vs.-V_{GS} transfer curves were taken under different bias voltages at T=1.8 K, B=−9 T. The hysteresis window was extracted using both the threshold voltage (V_{HW}) and threshold current (ΔVₜₕ, |I_{DS}|=10 nA) respectively, as shown in FIG. 7b. Two extraction methods showed similar results and they both showed no significant bias voltage dependence.

The frequency response of the hysteresis window is also studied and shown in FIG. 8. At the magnetic field of 9 T, four cycles of the |I_{DS}|-vs.-V_{GS} hysteresis curve were taken with different V_{GS} sweep rates. The extracted V_{HW} as a function of the cycle number is plotted. In the fast sweep limit (e.g., 2.178 V/s), it would take one or two cycles to ramp up to a stable V_{HW}, and this stable V_{HW} was smaller than that achieved with a much slower V_{GS} sweep rate. This behavior may be due to the slower response time for the electric polarization at low temperatures.

g. Note 5: Low-Temperature Magnetic Field-Dependent Electronic Transport Data on Additional Devices

FIG. 9 shows consistent high and low field behavior like FIG. 1 in the main text on two additional devices. FIG. 9a shows the |I_{DS}|-vs.-V_{GS} hysteresis under magnetic field from 9 T to −9 T with V_{DS}=0.4 V. The inset shows |I_{DS}|-vs.-V_{GS} hysteresis in the semi-log scale and it is clear this hysteresis is symmetric with respect to direction change of the out-of-plane magnetic field. FIG. 9b,c shows the V_{HW}, V_{th, H} and V_{th, L} extracted from the main panel of FIG. 9a. FIG. 9d-f shows this hysteresis is sensitive to a low field as small as 100 mT.

Magnetoresistance measurements of Device #5 are shown in FIG. 10. The measurement started from B=0, ramping up the gate voltage to 20 V and holding for the gate voltage for 10 minutes, which was followed by a magnetic field sweep sequence of B=0→14 T→0→−14 T→0 with a ramping rate of 10 mT/sec while the resistance was taken. No significant hysteresis was seen in consecutive four cycles; hence the data shown were averaged.

FIG. 11 shows a reversed magnetic field sweep right after measurement of FIG. 1c, where the only thing changed was the magnetic field ramping direction. It is shown that within the experimental error, V_{HW} does not have a magnetic hysteresis as seen in FIG. 11b.

h. Note 6: Magnetic Field-Independent Clockwise Hysteresis Above T_{C}

Above T_{C}, thermally activated and magnetic field-independent negative V_{HW} (clockwise hysteresis) was observed due to gate voltage¹³ stress and SiO₂—MoS₂ interfacial trapping states^{8,9}, as exemplified in FIG. 12a. In contrast, below T_{C}, magnetic field induced positive V_{HW} (counterclockwise hysteresis) was observed to be increasing at lower temperature, as shown in FIG. 12b.

i. Note 7|Additional Temperature-Dependent Measurements

FIG. 13 shows measurements like FIG. 2c,d on additional devices. Despite the fact that Device #5 was fabricated on a different batch and suffered from a finite Schottky barrier on its contacts, we found similar (although nosier) temperature-dependent behavior to those observed in ohmic-like Devices #1-#3. As summarized in FIG. 14c, comparable T_{C} (B) values within ±1 K were found.

### J. Note 8|Temperature Dependent Raman Spectroscopy

Temperature dependent Raman spectroscopy result is shown in FIG. 14a, where the E_{2g} and A_{1g} Raman modes of MoS₂ and a Raman mode of Si were extracted as shown in FIG. 14b. The green dashed line shows the linear fitting at temperatures higher than 100K, yielding a first-order temperature coefficient of −0.0106 cm⁻¹/K and −0.0114 cm⁻¹/K for A_{1g} and E_{2g} mode, respectively. These values are similar to previous studies²¹⁻²³.

k. Note 9|Notes on Scanning Tunneling Microscopy Studies

### Scanning Tunneling Microscopy on HOPG/MoS₂ Moiré Superlattice

The ML-MoS₂ sample for STM measurements was synthesized by CVD on an in situ cleaved HOPG substrate. The as-grown sample was then outgassed in situ at a temperature of 800 K and a vacuum of 2×10⁻¹⁰ Torr for an hour before measurements. The ML-MoS₂/HOPG sample was then transferred to an STM chamber and measured at 4.5 K under various magnetic fields using an electrochemical-etched tungsten tip, whose quality was verified by test measurements on Au (111) surface states. Further STM calibration was done by scanning on pure HOPG areas of the sample at 4.5 K prior to the study of sample area covered by a ML-MoS₂. Due to the lattice constant mismatch as well as a small twist angle between HOPG and the as-grown ML-MoS₂, moiré superlattice patterns were observed in the STM topography. As shown in FIGS. 15a-f, a bias voltage-dependent moiré topography was observed due to modified electronic coupling between HOPG and MoS₂, similar to the findings in ref²⁴. However, this dependence only changed the relative intensity rather than the position of the lattice points, as long as the Fermi level was kept within the band gap of MoS₂. Eventually, at a sufficiently large bias voltage of 0.7 V, a clear topography of the top-layer sulfur atoms emerged without moiré patterns (FIGS. 15 g, h). Therefore, a bias voltage of 0.7 V and a constant current of 2 nA were used to obtain the topography unless otherwise specified.

Extracting the ML-MoS₂ Lattice Expansion from Moiré Patterns

Moiré patterns are very sensitive to the lattice mismatch between ML-MoS₂ and the underlying HOPG, hence served as an excellent tool to accurately determined the MoS₂ lattice expansion by studying the STM topography of the same sample area under various constant magnetic fields. As exemplified in FIGS. 16a-d, fast Fourier transformation (FFT) was performed over the obtained raw topographic image, and then the MoS₂ lattice constant, moiré periodicity and twist angle were derived from studying the FFT pattern. Inverse FFT was performed on the filtered FFT image to obtain the filtered topography that highlighted the moiré pattern evolution under magnetic field.

Theoretical Modeling for Deriving the MoS₂ Lattice Expansion from Varying Moiré Patterns

Since the lattice constant of HOPG remains constant under magnetic field²⁵, the lattice match (δ) caused by magnetic field may be solely attributed to the changes in the ML-MoS₂ lattice constant so that δ=(a_{G}+a_{M}+Δa)/a_{G}, where a_{G}=0.246 nm and a_{M}=0.318 nm are the lattice constant of HOPG and ML-MoS₂ under zero magnetic field, respectively, and Δa is the ML-MoS₂ lattice expansion under a finite magnetic field²⁶. Given the twist angle (φ) between HOPG and MoS₂, the expected moiré pattern periodicity (λ) becomes

$$λ = \frac{( 1 + δ ) {a}_{G}}{\sqrt{2 ( 1 + δ ) ( 1 - cos φ ) + {δ}^{2}}} ( {ref}^{1} ) .$$

### 1. Note 10|Low Temperature Piezo-Response Force Microscopy (PFM) Measurements

To study the hysteresis behavior of ML-MoS₂ flakes on SiO₂/Si substrate under magnetic fields, piezo-response force microscopy (PFM) measurements were carried out at magnetic field strengths of B=0 and B=3 T at a temperature of 1.6 K, as shown in FIG. 17. The ferroelectric properties were analyzed using off-field piezo-response hysteresis loops to remove the electrostatic contributions. FIG. 17b displays the characteristic ferroelectric polarization switching through the butterfly hysteresis loops of PFM amplitude (blue) and phase (red) against the sample bias voltage. These results provide evidence for the presence of magnetic field-induced out-of-plane ferroelectricity in the ML-MoS₂ and demonstrate local point switching upon contact with a biased tip, as evidenced by the PFM hysteresis loops. Note that unlike the single polarity of the flexoelectric dipole induced by strain gradients, the ferroelectric hysteresis exhibits a pair of oppositely polarized states under a reversed field.

The hysteresis measurements using piezo-response force microscopy (PFM) were conducted utilizing a commercial cryogenic scanning probe microscope system (attoAFM I, Attocube) equipped with a closed-cycle cryostat (attoDRY 2100 with 9 T magnet, Attocube) operating at 1.6 K. A commercial platinum silicide (PtSi) coated tips with a spring constant of 2.8 N/m (NANOSENSORS PtSi-FM) was used to assess hysteresis, driven by a V_{RMS}=1.5 V ac voltage at a contact-resonance frequency of about 300 kHz. Off-field hysteresis loops were obtained by switching spectroscopic techniques under pulse sequences generated by an arbitrary waveform generator (G5100A, Picotest).

m. Note 11|Characterizing the Sulfur Vacancy Concentration

The sulfur vacancies in ML-MoS₂ may play an important role in our devices.

Therefore, a typical FET device (Dev. #5), which we believed to possess representative sulfur vacancy concentrations, was studied using Kelvin probe force microscopy (KPFM), as shown in FIG. 18. We also presented in FIG. 19 direct surface topography imaging of one ML-MoS₂ sample by STM, which revealed a sulfur vacancy level similar to the low density of sulfur vacancies ˜0.2% (Dev. #1-5) found in the ML-MoS₂ FET devices. The details are as follows.

The work function of the ML-MoS₂ was measured by the Peak Force Kelvin Probe Force Microscopy (PF-KPFM) calibrated with respect to the work function of gold at 4.82 eV⁴. The contact potential difference (CPD) between the tip and the sample is given by ΔV_{CPD}=ϕₛₐₘₚₗₑ−ϕₜᵢₚ, where ϕ is the work function. Therefore, the work function of the ML-MoS₂ sample becomes:

$${ϕ}_{{MoS}_{2}} = {ϕ}_{tip} + Δ {V}_{CPD}^{{MoS}_{2}} = {ϕ}_{Au} + Δ {V}_{CPD}^{{MoS}_{2}} - Δ {V}_{CPD}^{Au}$$

where ΔV_{CPD}^{MoS}^{₂} was measured to be 0.52±0.23 V, while ΔV_{CPD}^{Au} was measured to be 0.39±0.22 V in a scan size of (1 μm×1 μm, 512*512 grid) area on the fabricated Device #5. The Fermi level E_{F} is therefore determined from ϕ_{MoS}_{₂}˜4.9 eV, which is located 0.4 eV above at the intrinsic Fermi level (Eᵢ) of ML-MoS₂, as shown in the FIG. 14. Here we note that approximation of Eᵢ was used as Eᵢ can be expressed as Eᵢ=(E_{c}+Eᵥ+k_{B}T ln(mₚ*mₙ*))/2≈(E_{c}+Eᵥ)/2, where mₚ* and mₙ* are the effective mass of holes and electrons of MoS₂, respectively, and the k_{B}T ln(mₚ*/mₙ*) term is negligible comparing to (E_{c}+Eᵥ). The electron concentration of MoS₂ could be calculated with the following formula:

$$n = {n}_{i} exp ( \frac{{E}_{F} - {E}_{i}}{{k}_{B} T} )$$

where k_{B} is Boltzmann constant, T is the temperature, nᵢ, are the intrinsic electron concentration of MoS₂. With nᵢ˜10⁶ cm⁻² at room temperature²⁷ and measured E_{F}−Eᵢ=0.4 eV, the corresponding electron concentration of the MoS₂ sample was estimated as n ≈4.8×10¹² cm⁻². Assuming those electrons were induced by sulfur vacancies, the order of magnitude of sulfur vacancy population density can be estimated as na²\sqrt{3}/4˜0.2%, where a=0.318 nm is the lattice constant of MoS₂.

n. Note 12|Transport Studies on h-BN Buffered MoS₂ FETs

To investigate the role of substrate and strain induced by the mismatching thermal expansion coefficient between SiO₂ substrate and MoS₂, we fabricated ML-MoS₂ FETs with a buffer layer of ˜5 nm h-BN. The electrical transport results, as exemplified in FIG. 20, shows that the h-BN buffered device did not exhibit any emergence of counterclockwise hysteresis under a magnetic field up to ±9 T, which differed fundamentally from all ML-MoS₂ FET devices directly transferred on to SiO₂/Si, while the universally existent clockwise hysteresis due to gate voltage stress was observed. These results suggest that with low lateral friction between MoS₂ and h-BN, lattice expansion of the buffered ML-MoS₂ trends to be isotropic such that no significant horizontal mirror symmetry breaking occurred under magnetic field-induced lattice expansion. Therefore, no flexoelectric effect induced ferroelectric-like behavior was seen.

### Second Embodiment: FET on Strain Engineered Substrate

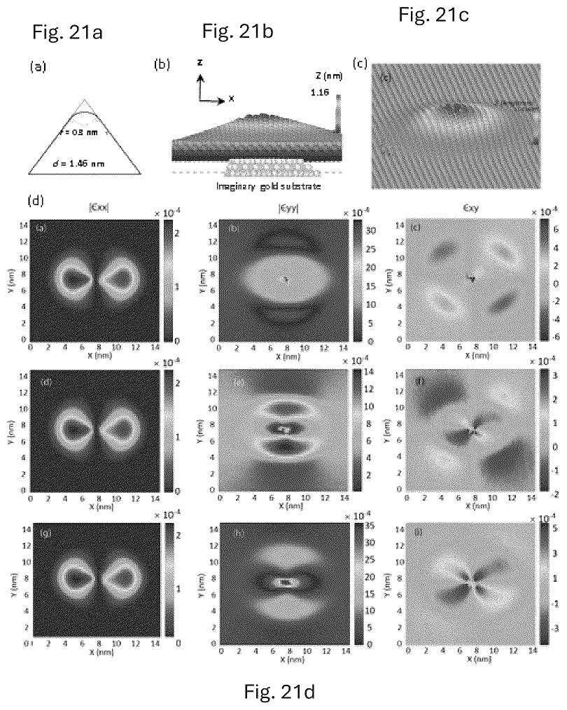

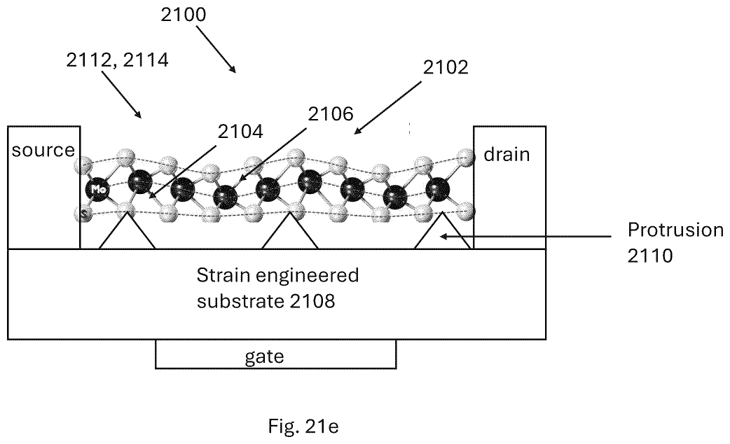

The measured correlation between asymmetric lattice expansion of the monolayer MoS₂ and the resulting ferroelectric response suggests that a strain engineered substrate can also be used to generate the ferroelectric response in the absence of magnetic field. FIG. 21a is a simulation illustrating the strain induced in the monolayer when the strain engineered substrate comprises nanostructures such as arrays of tetrahedrons (with the effect induced by one tetrahedron as an example).

Thus, in another embodiment illustrated in FIG. 21b, the device comprises a field effect transistor, comprising a strain engineered substrate; a monolayer of a single crystal semiconducting transition metal dichalcogenide (TMD) on the substrate; a source contact and a drain contact to the strained monolayer; and a gate contact on the substrate; wherein the a gate voltage applied to the gate contact with respect to the source contact modulates a ferroelectric response of the monolayer when strained by the strain engineered substrate consisting of arrays of fabricated nanostructures and a current through the monolayer between the source contact and the drain contact.

### Third Embodiment: FET as a Detector or Modulator/Transducer

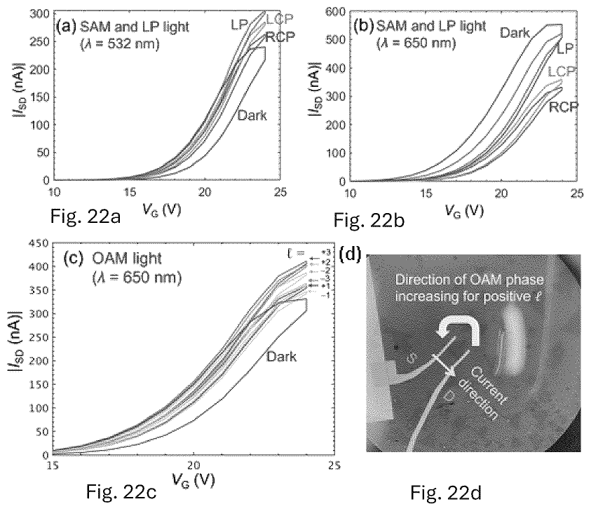

In yet another embodiment, a detector of twisted electromagnetic radiation (e.g., righthanded/lefthanded circularly polarized light, RCP/LCP light, and linearly polarized light, LP light) can be fabricated by coupling the FET to a circuit or other means for measuring the ferroelectric response and determining, from the ferroelectric response, a spin or orbital angular momentum state (e.g., which s or l state) of the twisted electromagnetic radiation incident on the monolayer. FIG. 22 illustrates detection of the OAM and spin state using the FET and shows the spin or orbital angular momentum of the incident twisted light can be measured from the hysteresis in the source drain current as a function of gate voltage (e.g., at least one of shape, size, or magnitude of the hysteresis loop).

An optoelectronic transducer or modulator, e.g., useful in a communications system, for example, can also be fabricated by coupling a source of twisted electromagnetic radiation to the FET so that the twisted electromagnetic radiation incident on the monolayer modulates the current with a spin or orbital angular momentum state of twisted electromagnetic radiation (e.g., such that spin or OAM state is transferred to the electrical current carrying the spin or orbital momentum state of the electromagnetic radiation).

These devices can be used to decode information carried by light, or in light controlled/gated electronics applications, for example.

### Process Steps

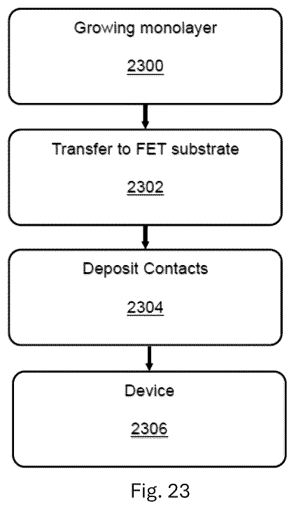

FIG. 23 is a flowchart illustrating a method of making an FET according to one or more embodiments.

Block 2300 represents growing a monolayer (ML) of TMD on a appropriate (e.g., sapphire) substrate, e.g., by chemical vapor deposition.

Block 2302 represents transferring the monolayer to a doped substrate suitable for gating the device In one or more examples, standard PMMA-assisted wet transfer technique can be used.

Block 2302 represents depositing source, drain, and gate contacts.

Block 2304 represents the end result, a device according to one or more embodiments.

The device can be embodied in many ways including, but not limited to, the following (referring to FIGS. 1-23).

1. A device 100, 2100 comprising:
a field effect transistor, comprising
a substrate 102;
a monolayer of a single crystal semiconducting transition metal dichalcogenide (TMD) 104 on the substrate;
a source contact 106 and a drain contact 108 to the strained monolayer; and
a gate contact 110 on the substrate; wherein the a gate voltage V_{GS} applied to the gate contact with respect to the source contact (or drain contact, or the channel) modulates a ferroelectric response of the monolayer when strained and a current through the monolayer between the source contact and the drain contact; and wherein:
the substrate is rigid and the monolayer experiences asymmetric lattice expansion when strained against the rigid substrate in response to an external magnetic field perpendicular to a surface of the monolayer and when cooled below 20 degrees Kelvin, or
the substrate is a strain engineered substrate 2108 inducing asymmetric lattice expansion 2112 of the monolayer.

2. A system 200 further comprising the device of embodiment 1, the system further comprising a controller 202; a magnetic field source 204 (e.g., magnet, electromagnet) for outputting a magnetic field across a thickness of the monolayer; and a cryogenic cooling system 206 (e.g., cryostat) for cooling the field effect transistor to a temperature below 20 Kelvin (or below the Curie temperature), wherein the controller controls the magnetic field and the temperature to tune the ferroelectric response.

3. The system of embodiment 1 or 2, further comprising a source 208 (e.g., a laser, light emitting device/diode) of twisted electromagnetic radiation coupled to the field effect transistor, further comprising controller controls at least one of a wavelength, polarization, or spin (e.g., s=+1 or −1) and orbital angular momentum (l=+2, +1, 0, −1, −2) of the electromagnetic radiation to tune or modulate the ferroelectric response and/or a photocurrent generated between the drain the source.

4. A detector of twisted electromagnetic radiation, comprising the device of any of the embodiments 1-3 coupled to a circuit 202 for measuring the ferroelectric response (shape or size or magnitude of the hysteresis loop) and determining, from the ferroelectric response, a spin or orbital angular momentum state (e.g., which s or l state) of the twisted electromagnetic radiation incident on the monolayer.

5. An optoelectronic transducer or modulator comprising the device of any of the embodiments 1-4, wherein the current is modulated with a spin or orbital angular momentum state of twisted electromagnetic radiation incident on the monolayer (e.g., as may be useful in a communication system).

6. The device of any of the embodiments 1-5, wherein the gate voltage is in a range of 0.1 V—up to a maximum voltage limited by dielectric leakage of the substrate, the magnetic field is in a range of 0.1 T to 12-T, and the temperature is in a range of 1-20 K.

7. The device of any of the embodiments 1-6, wherein the ferroelectric response is indirectly inferred by a hysteresis 210 in the current between the drain contact and source contact as a function of the gate voltage, wherein the hysteresis onset is at lower voltages for higher magnetic fields and lower temperatures. Polarization (force response to polarization measured using atomic force microscopy) as a function of applied gate voltage is a direct measurement of the polarization hysteresis associated with ferroelectricity, which has also been carried out as shown in FIG. 17 and confirmed that the electric hysteresis exhibited by the devices of the embodiments is associated with ferroelectric response.

8. The device of any of the embodiments 1-7, wherein the TMD comprises MoS₂, MoSe₂, WS₂, WSe₂ or an alloy thereof. Example alloys include, but not limited to, these compounds with S partially substituted with Se, Mo partially substituted with W, or S partially substituted with Te, so long as the monolayer remains in a semiconductor phase (not semimetal).

9. The device of any of the embodiments 1-8, wherein the monolayer comprises a top chalcogenide layer 2102, a bottom chalcogenide layer 2104; a transition metal layer 2106 between the chalcogenide layers, wherein the monolayer is under strain as characterized by measuring a different (e.g., greater) lattice expansion 2112 (using STM or Raman spectroscopy for example) induced by magnetic field or other straining mechanism, for the top layer as compared to the top layer. The expansion can comprise a ripple 2114 or undulation of the layers, wherein the top layer experiences larger amplitude ripples than the bottom layer.

10. The device of any of the embodiments 1-9, comprising low doping (e.g., less than 1%, e.g., 0.2% sulfur vacancies). In some embodiments, random doping with lots of vacancies impairs or weakens the mechanical response/elastic modulus, thereby inhibiting appearance of the ferroelectric response. In some embodiments, hysteresis disappears for more than 1% vacancies.

11. The device of any of the embodiments 1-10, wherein the strain engineered substrate 2108 further comprises an array of nanostructures or protrusions 2110 (e.g., nanodots, e.g., having a height and width in a range of 1-1000 nanometers) protruding on the substrate, wherein the monolayer in direct contact with the nanostructures conforms to a contour of the nanostructures so as to cause the asymmetric lattice expansion of the top and bottom layers (as evidenced by simulation). The height of each nanostructure may range from 1 nm to 10 nm, and the lateral dimension of each nanostructure may range from 5 nm to 50 n

12. The device of embodiment 11, wherein the array comprises a periodic array of the nanostructures or protrusions across an entire surface area of the monolayer, so as to contribute uniform asymmetric strain across the monolayer. The nanostructures or protrusions are spaced not too far apart (so that the strain is not too weak) nor so densely that the monolayer would crack.

13. The device of embodiment 11 or 12, wherein the nanostructures or protrusions each may comprise a tetrahedron (as an example) with a rounded top (to prevent cracking) and with one of its edges along the zig zag (x-axis) of the monolayer. However, any protrusion that doesn't cause breaking and provides enough strain can be used.

14. The device of any of the embodiments 1-13, wherein the substrate comprises a dielectric layer and the gate contact is on a backside of the substrate to apply the gate voltage across the dielectric layer.

15. The device of any of the embodiments 1-14 wherein the rigid substrate is silicon dioxide on silicon or other substrate that is rigid as compared to the monolayer, so that it does not move with the monolayer, or such that lattice expansion or contraction of the substrate is much less than the monolayer under application of the magnetic field. In some embodiments, the rigid substrate has a mechanical modulus much stronger (e.g., at least 10 times larger) than the monolayer.

16. The device of any of the embodiments 1-15, wherein the dielectric comprises a silicon dioxide layer on the doped silicon substrate or other material allowing application of a gate voltage across its thickness.

17. The device of any of the embodiments 1-16, wherein the strain engineered substrate comprises a monolayer of semiconducting TMD (e.g., as described herein) with the protrusions.

18. An optical detector, a memory, or sensitive magnetic sensor (at low temperatures below 20K) comprising the device of any of the embodiments 1-17.

19. The device of any of the embodiments 1-18, wherein other rigid semiconducting substrates potentially usable for the ML-TMD ferroelectric FETs may be based on III-V semiconductors such as GaAs and InGaAs, which may be doped with Al, and may use Al₂O₃ as the dielectric layer. Generally GaAs and related III-V compounds are excellent substrates for optical devices and may also be used for strain engineering.

20. The device of any of the embodiments 1-19 wherein the monolayer comprises a top chalcogenide layer 2102, a bottom chalcogenide layer 2104; a transition metal layer 2106 between the chalcogenide layers.

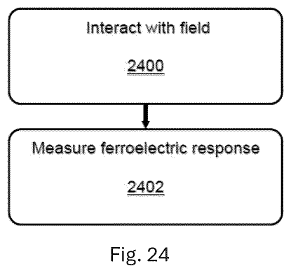

FIG. 24 illustrates a method of using the device.

Block 2400 represents interacting the monolayer TMD of the FET with a magnetic field or electromagnetic field.

Block 2402 represents measuring a (an out of plane) ferroelectric response of the monolayer in the FET in response to the magnetic field or electromagnetic field. The ferroelectric response can be measured from a hysteresis in the source drain current as a function of applied gate voltage, after confirmation of the ferroelectricity by measuring polarization as a function of applied electric field.

The method of FIG. 24 using the device of any of the embodiments 1-18.

### REFERENCES FOR FIRST EMBODIMENT (THESE REFERENCES ARE INCORPORATED BY REFERENCE HEREIN)

1. Si, M. et al. A ferroelectric semiconductor field-effect transistor. Nat. Electron. 2, 580-586 (2019).
2. Chai, X. et al. Nonvolatile ferroelectric field-effect transistors. Nat. Commun. 11, 2811 (2020).
3. Peng, Y. et al. Exploiting the Bulk Photovoltaic Effect in a 2D Trilayered Hybrid Ferroelectric for Highly Sensitive Polarized Light Detection. Angew. Chem. Int. Ed. 59, 3933-3937 (2020).
4. Late, D. J., Liu, B., Matte, H. S. S. R., Dravid, V. P. & Rao, C. N. R. Hysteresis in Single-Layer MoS₂ Field Effect Transistors. ACS Nano 6, 5635-5641 (2012).
5. Li, T., Du, G., Zhang, B. & Zeng, Z. Scaling behavior of hysteresis in multilayer MoS₂ field effect transistors. Appl. Phys. Lett. 105, 093107 (2014).
6. Illarionov, Y. Y. et al. The role of charge trapping in MoS₂/SiO₂ and MoS₂/hBN field-effect transistors. 2D Mater. 3, 035004 (2016).
7. Wang, Y. et al. Van der Waals contacts between three-dimensional metals and two-dimensional semiconductors. Nature 568, 70-74 (2019).
8. Uchino, K. Ferroelectric Devices. (CRC Press, 2018).
9. Morozovska, A. N., Eliseev, E. A., Svechnikov, G. S. & Kalinin, S. V. Pyroelectric response of ferroelectric nanowires: Size effect and electric energy harvesting. J. Appl. Phys. 108, 042009 (2010).
10. Shi, P.-P. et al. Symmetry breaking in molecular ferroelectrics. Chem. Soc. Rev. 45, 3811-3827 (2016).
11. Shirodkar, S. N. & Waghmare, U. V. Emergence of Ferroelectricity at a Metal-Semiconductor Transition in a 1 T Monolayer of MoS₂. Phys. Rev. Lett. 112, 157601 (2014).
12. Lipatov, A. et al. Direct observation of ferroelectricity in two-dimensional MoS2. Npj 2D Mater. Appl. 6, 18 (2022).
13. Yuan, S. et al. Room-temperature ferroelectricity in MoTe2 down to the atomic monolayer limit. Nat. Commun. 10, 1775 (2019).
14. Yang, T. H. et al. Ferroelectric transistors based on shear-transformation-mediated rhombohedral-stacked molybdenum disulfide. Nat. Electron. 7, 29-38 (2023).
15. Fei, Z. et al. Ferroelectric switching of a two-dimensional metal. Nature 560, 336-339 (2018).
16. Weston, A. et al. Interfacial ferroelectricity in marginally twisted 2D semiconductors. Nat. Nanotechnol. 17, 390-395 (2022).
17. Wang, X. et al. Interfacial ferroelectricity in rhombohedral-stacked bilayer transition metal dichalcogenides. Nat. Nanotechnol. 17, 367-371 (2022).
18. He, G. et al. Thermally Assisted Nonvolatile Memory in Monolayer MoS₂ Transistors. Nano Lett. 16, 6445-6451 (2016).
19. Kaushik, N. et al. Reversible hysteresis inversion in MoS2 field effect transistors. Npj 2D Mater. Appl. 1, 1-9 (2017).
20. Di Bartolomeo, A. et al. Hysteresis in the transfer characteristics of MoS₂ transistors. 2D Mater. 5, 015014 (2017).
21. Shu, J. et al. The intrinsic origin of hysteresis in MoS₂ field effect transistors. Nanoscale 8, 3049-3056 (2016).
22. Lee, Y.-H. et al. Synthesis of Large-Area MoS₂ Atomic Layers with Chemical Vapor Deposition. Adv. Mater. 24, 2320-2325 (2012).
23. Zhan, Y., Liu, Z., Najmaei, S., Ajayan, P. M. & Lou, J. Large-Area Vapor-Phase Growth and Characterization of MoS2 Atomic Layers on a SiO₂ Substrate. Small 8, 966-971 (2012).
24. AU—Simbulan, K. B. C., AU—Chen, P.-C., AU—Lin, Y.-Y. & AU—Lan, Y.-W. A Standard and Reliable Method to Fabricate Two-Dimensional Nanoelectronics. J. Vis. Exp. e57885 (2018) doi: 10.3791/57885.
25. Shen, P.-C. et al. Ultralow contact resistance between semimetal and monolayer semiconductors. Nature 593, 211-217 (2021).
26. Liu, X. et al. Charge-ferroelectric transition in ultrathin Na_{0.5}Bi_{4.5}Ti₄O₁₅ flakes probed via a dual-gated full van der Waals transistor. Adv. Mater. 32, 2004813 (2020).
27. Huang, L. F., Gong, P. L. & Zeng, Z. Correlation between structure, phonon spectra, thermal expansion, and thermomechanics of single-layer MoS₂. Phys. Rev. B 90, 045409 (2014).
28. Taube, A. et al. Temperature-Dependent Nonlinear Phonon Shifts in a Supported MoS₂ Monolayer. ACS Appl. Mater. Interfaces 6, 8959-8963 (2014).
29. Thripuranthaka, M., Kashid, R. V., Sekhar Rout, C. & Late, D. J. Temperature dependent Raman spectroscopy of chemically derived few layer MoS₂ and WS₂ nanosheets. Appl. Phys. Lett. 104, 081911 (2014).
30. Lee, K.-Y. et al. Raman imaging of strained bubbles and their effects on charge doping in monolayer WS2 encapsulated with hexagonal boron nitride. Appl. Surf. Sci. 604, 154489 (2022).
31. Geng, T. et al. A Novel Atomically Resolved Scanning Tunneling Microscope Capable of Working in Cryogen-Free Superconducting Magnet. Micromachines 14, 637 (2023).
32. Rice, C. et al. Raman-scattering measurements and first-principles calculations of strain-induced phonon shifts in monolayer MoS 2. Phys. Rev. B 87, 081307 (2013).
33. Sohier, T. et al. Enhanced Electron-Phonon Interaction in Multivalley Materials. Phys. Rev. X 9, 031019 (2019).
34. Khamrui, S., Bharti, K., Goldfarb, D., Das, T. & Banerjee, D. Strain-driven Charge Localisation and Spin Dynamics of Paramagnetic Defects in S-deficit 2H—MoS₂ Nanocrystals. Preprint at http://arxiv.org/abs/2312.12805 (2023).
35. Morozovska, A. N. et al. Flexoinduced ferroelectricity in low-dimensional transition metal dichalcogenides. Phys. Rev. B 102, 075417 (2020).
36. Luo, S. et al. Formation of ripples in atomically thin MoS2 and local strain engineering of electrostatic properties. Nanotechnology 26, 105705 (2015).
37. Wang, W., Yang, C., Bai, L., Li, M. & Li, W. First-Principles Study on the Structural and Electronic Properties of Monolayer MoS2 with S-Vacancy under Uniaxial Tensile Strain. Nanomaterials 8, 74 (2018).
38. Sevik, C. Assessment on lattice thermal properties of two-dimensional honeycomb structures: Graphene, h-BN, h-MoS₂, and h-MoSe₂. Phys. Rev. B 89, 035422 (2014).
39. Quereda, J., Castellanos-Gomez, A., Agraït, N. & Rubio-Bollinger, G. Single-layer MoS2 roughness and sliding friction quenching by interaction with atomically flat substrates. Appl. Phys. Lett. 105, 053111 (2014).
40. Kim, W. et al. Hysteresis Caused by Water Molecules in Carbon Nanotube Field-Effect Transistors. Nano Lett. 3, 193-198 (2003).
41. Li, Q. et al. Enhanced Valley Zeeman Splitting in Fe-Doped Monolayer MoS₂. ACS Nano 14, 4636-4645 (2020).
42. Marinov, K., Avsar, A., Watanabe, K., Taniguchi, T. & Kis, A. Resolving the spin splitting in the conduction band of monolayer MoS₂. Nat. Commun. 8, 1938 (2017).

### REFERENCES FOR SUPPLEMENTARY NOTES (THESE REFERENCES ARE INCORPORATED BY REFERENCE HEREIN)

1. Li, H. et al. From Bulk to Monolayer MoS₂: Evolution of Raman Scattering. Adv. Funct. Mater. 22, 1385-1390 (2012).
2. Splendiani, A. et al. Emerging Photoluminescence in Monolayer MoS₂. Nano Lett. 10, 1271-1275 (2010).
3. Allain, A., Kang, J., Banerjee, K. & Kis, A. Electrical contacts to two-dimensional semiconductors. Nat. Mater. 14, 1195-1205 (2015).
4. Shen, P.-C. et al. Ultralow contact resistance between semimetal and monolayer semiconductors. Nature 593, 211-217 (2021).
5. Radisavljevic, B., Radenovic, A., Brivio, J., Giacometti, V. & Kis, A. Single-layer MoS2 transistors. Nat. Nanotechnol. 6, 147-150 (2011).
6. Novoselov, K. S. et al. Two-dimensional atomic crystals.
7. Radisavljevic, B. & Kis, A. Mobility engineering and a metal-insulator transition in monolayer MoS2. Nat. Mater. 12, 815-820 (2013).
8. He, G. et al. Thermally Assisted Nonvolatile Memory in Monolayer MoS₂ Transistors. Nano Lett. 16, 6445-6451 (2016).
9. Kaushik, N. et al. Reversible hysteresis inversion in MoS2 field effect transistors. Npj 2D Mater. Appl. 1, 1-9 (2017).
10. Di Bartolomeo, A. et al. Hysteresis in the transfer characteristics of MoS₂ transistors. 2D Mater. 5, 015014 (2017).
11. Late, D. J., Liu, B., Matte, H. S. S. R., Dravid, V. P. & Rao, C. N. R. Hysteresis in Single-Layer MoS₂ Field Effect Transistors. ACS Nano 6, 5635-5641 (2012).
12. Li, T., Du, G., Zhang, B. & Zeng, Z. Scaling behavior of hysteresis in multilayer MoS2 field effect transistors. Appl. Phys. Lett. 105, 093107 (2014).
13. Shu, J. et al. The intrinsic origin of hysteresis in MoS₂ field effect transistors. Nanoscale 8, 3049-3056 (2016).
14. Shimazu, Y., Murata, K. & Toda, S. Anomalous hysteresis below 1 K in the transfer characteristics of MoS2 field effect transistors. Jpn. J. Appl. Phys. 54, 031201 (2015).
15. Xie, J. et al. Analysis of Schottky barrier heights and reduced Fermi-level pinning in monolayer CVD-grown MoS2 field-effect-transistors. Nanotechnology 33, 225702 (2022).
16. Lee, J. et al. Electrical role of sulfur vacancies in MoS2: Transient current approach. Appl. Surf. Sci. 613, 155900 (2023).
17. Noh, J.-Y., Kim, H. & Kim, Y.-S. Stability and electronic structures of native defects in single-layer MoS 2. Phys. Rev. B 89, 205417 (2014).
18. Jadwiszczak, J. et al. MoS₂ Memtransistors Fabricated by Localized Helium Ion Beam Irradiation. ACS Nano 13, 14262-14273 (2019).
19. Shevliakova, H. V. et al. Flexoelectric and Piezoelectric Coupling in a Bended MoS2 Monolayer. Symmetry 13, 2086 (2021).
20. Xiao, W.-Z., Luo, H.-J. & Xu, L. Elasticity, piezoelectricity, and mobility in two-dimensional BiTeI from a first-principles study. J. Phys. Appl. Phys. 53, 245301 (2020).
21. Yan, R. et al. Thermal Conductivity of Monolayer Molybdenum Disulfide Obtained from Temperature-Dependent Raman Spectroscopy. ACS Nano 8, 986-993 (2014).
22. Najmaei, S., Ajayan, P. M. & Lou, J. Quantitative analysis of the temperature dependency in Raman active vibrational modes of molybdenum disulfide atomic layers. Nanoscale 5, 9758 (2013).
23. Lanzillo, N. A. et al. Temperature-dependent phonon shifts in monolayer MoS₂. Appl. Phys. Lett. 103, 093102 (2013).
24. Chen, P. et al. Tunable Moiré Superlattice of Artificially Twisted Monolayers. Adv. Mater. 31, 1901077 (2019).
25. Geng, T. et al. A Novel Atomically Resolved Scanning Tunneling Microscope Capable of Working in Cryogen-Free Superconducting Magnet. Micromachines 14, 637 (2023).
26. Abbas, G. et al. Recent Advances in Twisted Structures of Flatland Materials and Crafting Moiré Superlattices. Adv. Funct. Mater. 30, 2000878 (2020).
27. Ma, X. Y. Study of the Electrical Properties of Monolayer MoS₂ Semiconductor. Adv. Mater. Res. 651, 193-197 (2013).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A device, comprising:
a field effect transistor, comprising
a substrate;
a monolayer of a single crystal semiconducting transition metal dichalcogenide (TMD) on the substrate;
a source contact and a drain contact to the strained monolayer; and
a gate contact on the substrate; wherein the a gate voltage applied to the gate contact with respect to the source contact modulates a ferroelectric response of the monolayer when strained and a current through the monolayer between the source contact and the drain contact; and wherein:
the substrate is rigid and the monolayer experiences asymmetric lattice expansion when strained against the rigid substrate in response to an external magnetic field perpendicular to a surface of the monolayer and when cooled below 20 degrees Kelvin, or
the substrate is a strain engineered substrate inducing asymmetric lattice expansion of the monolayer.

2. A system further comprising the device of claim 1, the system further comprising a controller; a magnetic field source for outputting a magnetic field across a thickness of the monolayer; and a cryogenic cooling system for cooling the field effect transistor to a temperature below 20 Kelvin (or below the Curie temperature), wherein the controller controls the magnetic field and the temperature to tune the ferroelectric response.

3. The system of claim 1, further comprising a source of twisted electromagnetic radiation coupled to the field effect transistor, further comprising controller controls at least one of a wavelength, polarization, spin, or orbital angular momentum of the electromagnetic radiation to tune or modulate the ferroelectric response and/or a photocurrent generated between the drain the source in response to the twisted electromagnetic radiation.

4. A detector of twisted electromagnetic radiation, comprising the device of claim 1 coupled to a circuit for measuring the ferroelectric response (shape or size or magnitude of the hysteresis loop) and determining, from the ferroelectric response, a spin or orbital angular momentum state (e.g., which s or l state) of the twisted electromagnetic radiation incident on the monolayer.

5. An optoelectronic transducer or modulator comprising the device of claim 1, wherein the current is modulated with a spin or orbital angular momentum state of twisted electromagnetic radiation incident on the monolayer.

6. The device of claim 1, wherein the gate voltage is in a range of 0.1 V—up to a maximum voltage limited by dielectric leakage of layer in the substrate, the magnetic field is in a range of 0.1 T to 12-T, and the temperature is in a range of 1-20 Kelvin.

7. The device of claim 1, wherein the ferroelectric response is characterized by a hysteresis in the current between the drain and source as a function of the gate voltage, wherein the hysteresis onset is at lower voltages for higher magnetic fields and lower temperatures.

8. The device of claim 1, wherein the TMD comprises MoS₂, MoSe₂, WS₂, WSe₂ or an alloy thereof.

9. The device of claim 1, wherein the monolayer comprises a top chalcogenide layer, a bottom chalcogenide layer, and a transition metal between the chalcogenide layers, and the monolayer is under strain as characterized by measuring a different (larger) lattice expansion in the top chalcogenide layer as compared to the bottom chalcogenide layer.

10. The device of claim 9, wherein the strain engineered substrate comprises an array of nanostructures protruding on the substrate, wherein the monolayer in direct contact with the nanostructures conforms to a contour of the nanostructures to form the strain.

11. The device of claim 10, wherein the nanostructures each comprise a tetrahedron with a rounded top.

12. The device of claim 10, wherein the strain engineered substrate comprises a transition metal dichalcogenide.

13. The device of claim 1, wherein the substrate comprises a dielectric layer and the gate contact is on a backside of the substrate to apply the gate voltage across the dielectric layer.

14. The device of claim 13, wherein the dielectric comprises a silicon dioxide layer on the doped silicon substrate.

15. An optical detector, a memory, or magnetic sensor comprising the device of claim 1.

16. A method of making a device, comprising:
growing a monolayer of a single crystal semiconducting transition metal dichalcogenide (TMD) on a first substrate;
transferring the monolayer to a second substrate;
depositing a source contact; a drain contact; and a gate contact to the monolayer;
coupling a first circuit to apply a gate voltage to the gate contact with respect to the source contact and a source-drain voltage between the source contact and the drain contact; and
coupling a second circuit to measure a ferroelectric response of the monolayer when strained.

17. A method of using a device, comprising:
straining a monolayer of TMD as an active region of a field effect transistor; and
measuring a ferroelectric response of the monolayer.
